(19) United States
(12) Patent Application Publication
(10) Pub. No.: US 2024/0276121 A1
(43) Pub. Date: Aug. 15, 2024

(54) IMAGING ELEMENT AND IMAGING DEVICE

(71) Applicant: SONY SEMICONDUCTOR SOLUTIONS CORPORATION, KANAGAWA (JP)

(72) Inventors: YOSHIHIDE KOMATSU, KANAGAWA (JP); MASAHIKO SAGISAKA, KANAGAWA (JP); SHOUICHIROU SHIRAISHI, KUMAMOTO (JP); KENTAROU OGATA, KANAGAWA (JP); TAKAHIRO ABIRU, KANAGAWA (JP); YASUHIRO KANEO, KANAGAWA (JP); KATSUYA YACHI, KANAGAWA (JP)

(21) Appl. No.: 18/681,927

(22) PCT Filed: Mar. 9, 2022
(86) PCT No.: PCT/JP2022/010183

§ 371 Date: Feb. 7, 2024

(30) Foreign Application Priority Data
Sep. 9, 2021 (JP) 2021-147124

(51) Int. Cl. H04N 25/77; H04N 23/667; H04N 25/616

(52) U.S. Cl. CPC H04N 25/77; H04N 23/667; H04N 25/616

(57) ABSTRACT

A time required for resetting a pixel is shortened. An imaging element includes a plurality of pixel blocks each including a plurality of pixels each including a photoelectric conversion unit and a charge transfer unit, a charge holding unit that holds a charge transferred by the charge transfer unit, a reset unit, and an image signal generation unit that generates an image signal according to the held charge, an auxiliary charge holding unit that couples to the charge holding unit of each of the plurality of pixel blocks; and a coupling unit that is disposed for each of the plurality of pixel blocks and couples the auxiliary charge holding unit to the charge holding unit, in which the image signal generation unit generates the image signal in each of a high sensitivity mode in which the auxiliary charge holding unit and the charge holding unit are not coupled and a low sensitivity mode in which the auxiliary charge holding unit and the charge holding unit are coupled, the coupling unit causes conduction between the charge holding unit and the auxiliary charge holding unit in a low sensitivity mode, an own pixel block charge holding period, and a charge non-holding period, and the reset unit performs the reset in the low sensitivity mode and the charge non-holding period.

### FIELD

The present disclosure relates to an imaging element and an imaging device.

### BACKGROUND

An imaging element is used in which pixel blocks each including a plurality of pixels and a readout circuit shared by the pixels are arranged in a two-dimensional matrix in the imaging element. In this pixel block, a floating diffusion region (FD) that is a semiconductor region to which charges generated by the pixels are transferred is disposed, and the readout circuit generates an image signal corresponding to the charge transferred to and held by the FD. Since the readout circuit is shared by a plurality of pixels, the imaging element can be reduced as compared with a case where the readout circuit is disposed for each pixel. As such an imaging element, an imaging element including an auxiliary capacitance for adjusting the capacitance of the FD for each pixel block has been proposed (see, for example, Patent Literature 1). This auxiliary capacitance is coupled to the FD via a MOS transistor. By switching conduction and non-conduction of the MOS transistor, the capacitance of the FD can be adjusted, and the sensitivity of the pixel can be adjusted.

### CITATION LIST

### Patent Literature

Patent Literature 1: JP 2015-028780 A

### SUMMARY

### Technical Problem

However, in the above-described conventional technique, since the auxiliary capacitance is added, it takes time to reset discharging the charges of the FD, and there is a problem that the time necessary for the image signal increases and a frame frequency decreases.

Therefore, the present disclosure proposes an imaging element and an imaging device that reduce a time necessary for resetting a pixel and reduce a decrease in a frame frequency.

### Solution to Problem

An imaging element according to the present disclosure includes: a plurality of pixel blocks each including a plurality of pixels each including a photoelectric conversion unit that performs photoelectric conversion of incident light from a subject and a charge transfer unit that transfers a charge generated by the photoelectric conversion, a charge holding unit that holds a charge transferred by the charge transfer unit, a reset unit that performs reset by discharging the held charge, and an image signal generation unit that generates an image signal according to the held charge; an auxiliary charge holding unit coupled to the charge holding unit of each of the plurality of pixel blocks; and a coupling unit that is disposed for each of the plurality of pixel blocks and couples the auxiliary charge holding unit to the charge holding unit by causing conduction between the charge holding unit and the auxiliary charge holding unit of the pixel block containing the coupling unit, wherein the image signal generation unit generates the image signal in each of a high sensitivity mode which is an operation mode in which the auxiliary charge holding unit and the charge holding unit are not coupled and a low sensitivity mode which is an operation mode in which the auxiliary charge holding unit and the charge holding unit are coupled, the coupling unit causes, in a case of the low sensitivity mode, conduction between the charge holding unit and the auxiliary charge holding unit during an own pixel block charge holding period that is a period in which a charge is held in the charge holding unit of the pixel block of the coupling unit and a charge non-holding period that is a period in which a charge is not held in the charge holding unit of any of the pixel blocks, and the reset unit performs the reset in the charge non-holding period in a case of the low sensitivity mode.

### BRIEF DESCRIPTION OF DRAWINGS

FIG. 1 is a diagram depicting a configuration example of an imaging element according to an embodiment of the present disclosure.

FIG. 2 is a diagram illustrating a configuration example of a pixel block according to a first embodiment of the present disclosure.

FIG. 3 is a diagram illustrating an example of a circuit configuration of the pixel block according to the first embodiment of the present disclosure.

FIG. 4 is a cross-sectional view illustrating a configuration example of pixels according to an embodiment of the present disclosure.

FIG. 5 is a diagram illustrating a configuration example of a column signal processing unit according to the embodiment of the present disclosure.

FIG. 6 is a diagram illustrating an example of generation of an image signal according to the first embodiment of the present disclosure.

FIG. 7A is a diagram illustrating another configuration example of an imaging element according to the first embodiment of the present disclosure.

FIG. 7B is a diagram illustrating another configuration example of the imaging element according to the first embodiment of the present disclosure.

FIG. 8 is a diagram illustrating an example of generation of an image signal according to a second embodiment of the present disclosure.

FIG. 9A is a diagram illustrating an example of charge transfer according to the second embodiment of the present disclosure.

FIG. 9B is a diagram illustrating an example of charge transfer according to the second embodiment of the present disclosure.

FIG. 9C is a diagram illustrating an example of charge transfer according to the second embodiment of the present disclosure.

FIG. 10A is a diagram illustrating an example of charge transfer according to a conventional embodiment.

FIG. 10B is a diagram illustrating an example of charge transfer according to the conventional embodiment.

FIG. 10C is a diagram illustrating an example of charge transfer according to the conventional embodiment.

FIG. 10D is a diagram illustrating an example of charge transfer according to the conventional embodiment.

FIG. 10E is a diagram illustrating an example of charge transfer according to the conventional embodiment.

FIG. 11 is a diagram illustrating a configuration example of a pixel block according to a third embodiment of the present disclosure.

FIG. 12 is a diagram illustrating an example of a circuit configuration of a pixel block according to the third embodiment of the present disclosure.

FIG. 13A is a diagram illustrating an example of generation of a phase difference signal according to the third embodiment of the present disclosure.

FIG. 13B is a diagram illustrating an example of generation of the phase difference signal according to the third embodiment of the present disclosure.

FIG. 13C is a diagram illustrating an example of generation of the phase difference signal according to the third embodiment of the present disclosure.

FIG. 13D is a diagram illustrating an example of generation of the phase difference signal according to the third embodiment of the present disclosure.

FIG. 14 is a diagram illustrating a configuration example of an analog-to-digital conversion unit according to the third embodiment of the present disclosure.

FIG. 15 is a diagram illustrating an example of generation of an image signal according to the third embodiment of the present disclosure.

FIG. 16 is a diagram illustrating a configuration example of an imaging device to which the technology according to the present disclosure can be applied.

### DESCRIPTION OF EMBODIMENTS

Hereinafter, embodiments of the present disclosure will be described in detail with reference to the drawings. The description will be given in the following order. Note that in each of the following embodiments, the same parts are denoted by the same reference numerals, and redundant description will be omitted.
1. First Embodiment
2. Second Embodiment
3. Third Embodiment
4. Configuration of Imaging Device

### 1. First Embodiment

### [Configuration of Imaging Element]

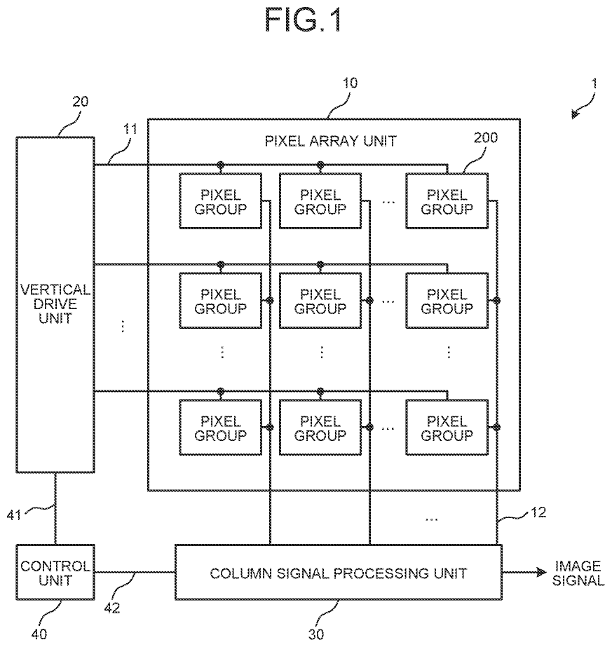

FIG. 1 is a diagram illustrating a configuration example of an imaging element according to an embodiment of the present disclosure. The drawing is a block diagram illustrating a configuration example of an imaging element 1. The imaging element 1 is a semiconductor element that generates image data of a subject. The imaging element 1 includes a pixel array unit 10, a vertical drive unit 20, a column signal processing unit 30, and a control unit 40.

The pixel array unit 10 is formed by arranging a plurality of pixel blocks 200. In the pixel array unit 10, a plurality of pixel blocks 200 is disposed in a shape of a two-dimensional matrix. Here, the pixel blocks 200 each include a plurality of pixels having a photoelectric conversion unit that performs photoelectric conversion of incident light, and a charge holding unit (charge holding unit 103 to be described later) that holds a charge generated by photoelectric conversion. Further, an image signal generation unit (image signal generation unit 110 to be described later) is disposed for each pixel block 200. The image signal generation unit 110 generates an image signal on the basis of the charge held in a charge holding unit 103 of the pixel block 200. For example, a photodiode can be used as the photoelectric conversion unit.

A signal line 11 is wired to each pixel block 200 and the image signal generation unit 110. The pixel block 200 and the image signal generation unit 110 are controlled by a control signal transmitted by the signal line 11. Furthermore, a signal line 12 is wired to the image signal generation unit 110. An image signal is output from the image signal generation unit 110 to the signal line 12. Note that the signal line 11 is disposed for each row of the shape of the two-dimensional matrix, and is commonly wired to the plurality of pixel blocks 200 and the image signal generation unit 110 disposed in one row. The signal lines 12 are disposed in the column direction of the two-dimensional matrix.

The vertical drive unit 20 generates a control signal for the pixel block 200 described above. The vertical drive unit 20 in the drawing generates a control signal for each row of the two-dimensional matrix of the pixel array unit 10 and sequentially outputs the control signal via the signal line 11. Note that the vertical drive unit 20 is an example of a control signal generation unit described in the claims.

The column signal processing unit 30 processes the image signal generated by the pixel block 200. The column signal processing unit 30 in the drawing simultaneously processes image signals from the plurality of pixel blocks 200 disposed in one row of the pixel array unit 10 transmitted via the signal line 12. As this processing, for example, analog-to-digital conversion for converting an analog image signal generated by the pixel block 200 into a digital image signal and correlated double sampling (CDS) for removing an offset error of the image signal can be performed. The processed image signal is output to a circuit or the like outside the imaging element 1.

The control unit 40 controls the vertical drive unit 20 and the column signal processing unit 30. The control unit 40 in the drawing outputs control signals via respective signal lines 41 and 42 to control the vertical drive unit 20 and the column signal processing unit 30.

### [Configuration of Pixel Block]

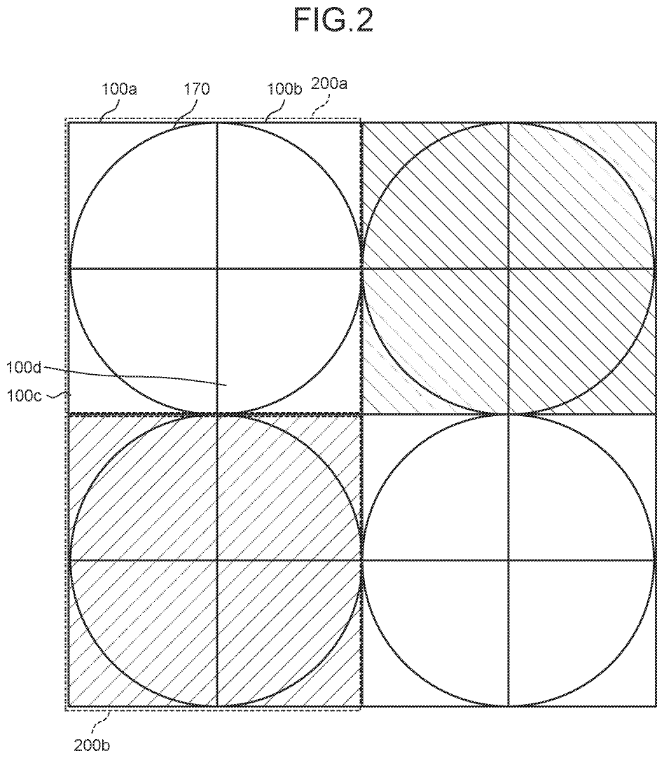

FIG. 2 is a diagram illustrating a configuration example of a pixel block according to the first embodiment of the present disclosure. The drawing is a block diagram illustrating a configuration example of the pixel block 200. The pixel block 200 includes a plurality of pixels 100. The pixel block 200 in the drawing represents an example including four pixels 100 of pixels 100a, 100b, 100c, and 100d. Furthermore, a charge holding unit (charge holding unit 103 to be described later) that holds a charge generated by photoelectric conversion of the pixel 100, an auxiliary charge holding unit (an auxiliary charge holding unit 108 to be described later) that couples to the charge holding unit 103, and an image signal generation unit 110 are disposed for each pixel block 200. Furthermore, the charge holding units 103 are connected to each other in the pixel blocks 200 (a pixel block 200a and a pixel block 200b) vertically adjacent in the drawing.

In the pixel 100, a photoelectric conversion unit and a charge transfer unit (not illustrated) are disposed. As will be described later, a photoelectric conversion unit 101a and a charge transfer unit 102a are disposed in the pixel 100a in the drawing. In the pixel 100b in the drawing, a photoelectric conversion unit 101b and a charge transfer unit 102b are disposed. In the pixel 100c in the drawing, a photoelectric conversion unit 101c and a charge transfer unit 102c are disposed. In the pixel 100d in the drawing, a photoelectric conversion unit 101d and a charge transfer unit 102d are disposed.

As described above, a photoelectric conversion unit 101 and the like perform photoelectric conversion of incident light. In addition, the charge holding unit 103 holds a charge generated by photoelectric conversion. The charge holding unit 103 can be constituted by a semiconductor region having a relatively high impurity concentration formed in a semiconductor substrate on which the pixel 100 is formed. Such a semiconductor region is referred to as a floating diffusion region (FD) . The charge transfer unit is disposed for each pixel 100, and transfers the charge generated and held by the photoelectric conversion unit 101 to the charge holding unit 103. As will be described later, the charge transfer unit can include a MOS transistor.

Furthermore, an on-chip lens that condenses incident light from a subject is disposed in the pixel 100. A circle described in the pixel 100 in the drawing represents an on-chip lens 170. An example in which the on-chip lens 170 in the drawing is commonly disposed in the four pixels 100a, 100b, 100c, and 100d is illustrated. Note that a color filter (color filter 150 described later) can be disposed in the pixel 100. The color filter 150 is an optical filter that transmits incident light having a predetermined wavelength out of the incident light. As the color filter 150, three types of color filters that transmit red light, green light, and blue light can be used. Furthermore, the same type of color filters 150 can be disposed in the pixels 100 disposed in the pixel block 200. That is, different color filters 150 can be disposed for each pixel block 200. In the drawing, an outlined rectangle represents the color filter 150 that transmits green light. Further, a diagonally hatched rectangle extending downward to the right represents the color filter 150 that transmits blue light. Furthermore, a diagonally hatched rectangle extending upward to the right represents the color filter 150 that transmits red light. In this manner, the color filters 150 can be disposed in the Bayer array with respect to the pixel block 200.

Note that, since the on-chip lens 170 in the drawing is commonly disposed in the pixels 100a to 100d, it is possible to generate a phase difference signal for detecting an image plane phase difference by pupil division of a subject. The pixels 100a to 100d can be subjected to pupil division in a left-right direction and an up-down direction in the drawing.

### [Circuit Configuration of Pixel Block]

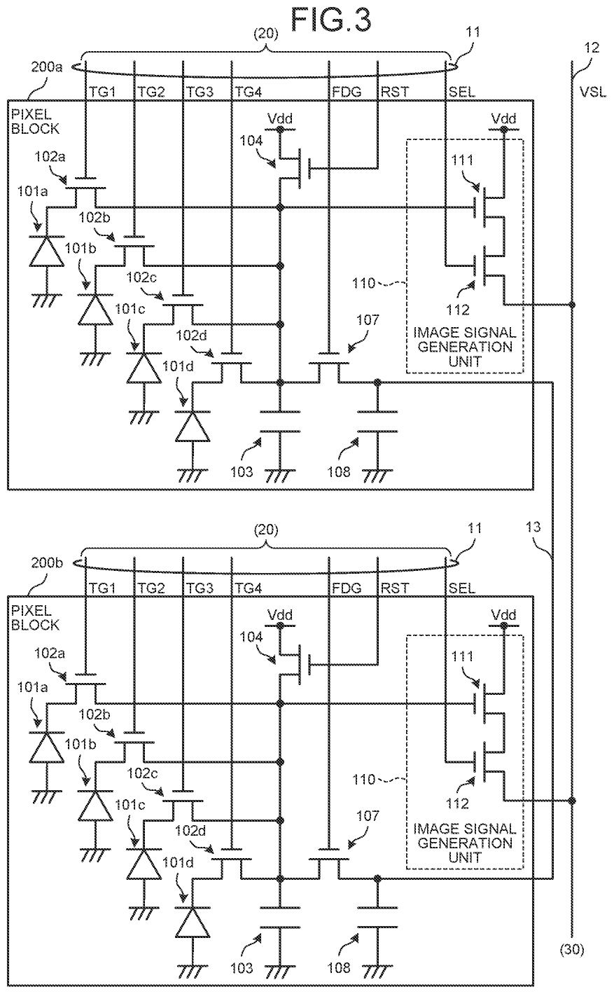

FIG. 3 is a diagram illustrating an example of a circuit configuration of a pixel block according to the first embodiment of the present disclosure. The drawing is a circuit diagram illustrating a configuration example of the pixel blocks 200a and 200b.

The pixel block 200a includes photoelectric conversion units 101a, 101b, 101c, and 101d, charge transfer units 102a, 102b, 102c, and 102d, a charge holding unit 103, a reset unit 104, an amplification transistor 111, and a selection transistor 112. Furthermore, the pixel block 200a further includes an auxiliary charge holding unit 108 and a coupling unit 107. Note that the circuits of the amplification transistor 111 and the selection transistor 112 constitute the image signal generation unit 110. Furthermore, the photoelectric conversion unit 101a and the charge transfer unit 102a, and the photoelectric conversion unit 101b and the charge transfer unit 102b constitute a pixel 100a and a pixel 100b (not illustrated), respectively. Furthermore, the photoelectric conversion unit 101c and the charge transfer unit 102c, and the photoelectric conversion unit 101d and the charge transfer unit 102d constitute a pixel 100c and a pixel 100d (not illustrated), respectively.

The charge transfer units 102a to 102d, the reset unit 104, the amplification transistor 111, the selection transistor 112, and the coupling unit 107 can include n-channel MOS transistors. In addition, the auxiliary charge holding unit 108 can be configured by a semiconductor region similar to the FD.

As described above, the signal lines 11 to 13 are wired in the pixel block 200a. The signal line 11 in the drawing includes a signal line TG1, a signal line TG2, a signal line TG3, a signal line TG4, a signal line FDG, a signal line RST, and a signal line SEL. In addition, the signal line 12 includes a signal line VSL. Furthermore, the signal line 13 is a signal line that connects the pixel block 200a and the pixel block 200b. In addition, a power supply line Vdd is wired to the pixel block 200a. The power supply line Vdd is a wiring that supplies power to the pixel block 200a.

An anode of the photoelectric conversion unit 101a is grounded, and a cathode is connected to a source of the charge transfer unit 102a. An anode of the photoelectric conversion unit 101b is grounded, and a cathode is connected to a source of the charge transfer unit 102b. An anode of the photoelectric conversion unit 101c is grounded, and a cathode is connected to a source of the charge transfer unit 102c. An anode of the photoelectric conversion unit 101d is grounded, and a cathode is connected to a source of the charge transfer unit 102d. Drains of the charge transfer unit 102a, the charge transfer unit 102b, the charge transfer unit 102c, and the charge transfer unit 102d are commonly connected to one end of the charge holding unit 103. Furthermore, a gate of the amplification transistor 111, a source of the reset unit 104, and a drain of the coupling unit 107 are further connected to one end of the charge holding unit 103. The other end of the charge holding unit 103 is grounded. The drain of the reset unit 104 and the drain of the amplification transistor 111 are connected to the power supply line Vdd. A source of the amplification transistor 111 is connected to a drain of the selection transistor 112, and a source of the selection transistor 112 is connected to the signal line VSL.

A gate of the charge transfer unit 102a is connected to the signal line TG1. A gate of the charge transfer unit 102b is connected to the signal line TG2. A gate of the charge transfer unit 102c is connected to the signal line TG3. A gate of the charge transfer unit 102d is connected to the signal line TG4. A gate of the reset unit 104 is connected to the signal line RST. A gate of the coupling unit 107 is connected to the signal line FDG. One end of the auxiliary charge holding unit 108 is grounded, and the other end is connected to a source of the coupling unit 107 and the signal line 13.

The reset unit 104 resets the charge holding unit 103. This reset can be performed by discharging the charge of the charge holding unit 103 by conducting between the charge holding unit 103 and the power supply line Vdd. A control signal of the reset unit 104 is transmitted by the signal line RST.

The amplification transistor 111 amplifies the voltage of the charge holding unit 103. A gate of the amplification transistor 111 is connected to the charge holding unit 103. Therefore, an image signal having a voltage corresponding to the charge held in the charge holding unit 103 is generated at the source of the amplification transistor 111. Further, by making the selection transistor 112 conductive, this image signal can be output to the signal line VSL. A control signal of the selection transistor 112 is transmitted by the signal line SEL.

The auxiliary charge holding unit 108 is a capacitor coupled to the charge holding unit 103. By coupling the auxiliary charge holding unit 108 to the charge holding unit 103, the charge holding capacitance of the pixel block 200a can be adjusted. By coupling the auxiliary charge holding unit 108 to the charge holding unit 103, the charge holding capacitance of the pixel block 200a increases. Thus, the sensitivity of the pixel block 200a can be reduced. In a case where the auxiliary charge holding unit 108 is not coupled to the charge holding unit 103, the charge holding capacitance of the pixel block 200a becomes relatively high, and saturation of charges is likely to occur. An operation mode in which the auxiliary charge holding unit 108 is not coupled to the charge holding unit 103 and the operation mode in which the auxiliary charge holding unit 108 is coupled to the charge holding unit 103 are referred to as a high sensitivity mode and a low sensitivity mode, respectively.

The coupling unit 107 couples the auxiliary charge holding unit 108 to the charge holding unit 103. The coupling unit 107 includes a MOS transistor, and can couple the auxiliary charge holding unit 108 to the charge holding unit 103 by conducting the charge holding unit 103 and the auxiliary charge holding unit 108.

Since the circuit configuration of the pixel block 200b is similar to that of the pixel block 200a, the description thereof will be omitted. Note that the auxiliary charge holding units 108 of the pixel block 200a and the pixel block 200b are connected by the signal line 13.

As described above, a charge transfer unit 102, the reset unit 104, the selection transistor 112, and the coupling unit 107 can include n-channel MOS transistors. In this n-channel MOS transistor, a drain and a source can be conducted by applying a voltage exceeding a threshold of a gate-source voltage Vgs to the gate. Hereinafter, a voltage exceeding the threshold of the gate-source voltage Vgs is referred to as an on-voltage. On the other hand, a voltage that brings the MOS transistor into a non-conductive state is referred to as an off-voltage. The control signal including the on-voltage and the off-voltage is transmitted by the signal line TG1 or the like.

Further, when the reset unit 104 resets the charge holding unit 103, the photoelectric conversion unit 101 can also be reset by making the charge transfer unit 102 conductive. Furthermore, the auxiliary charge holding unit 108 can be reset by making the coupling unit 107 conductive. The reset of the auxiliary charge holding unit 108 can be performed during an own pixel block charge holding period which is a period in which a charge is held in the charge holding unit 103 of the pixel block 200 and a charge non-holding period which is a period in which a charge is not held in the charge holding unit 103 of any pixel block 200.

### [Configuration of Cross-Section of Imaging Element]

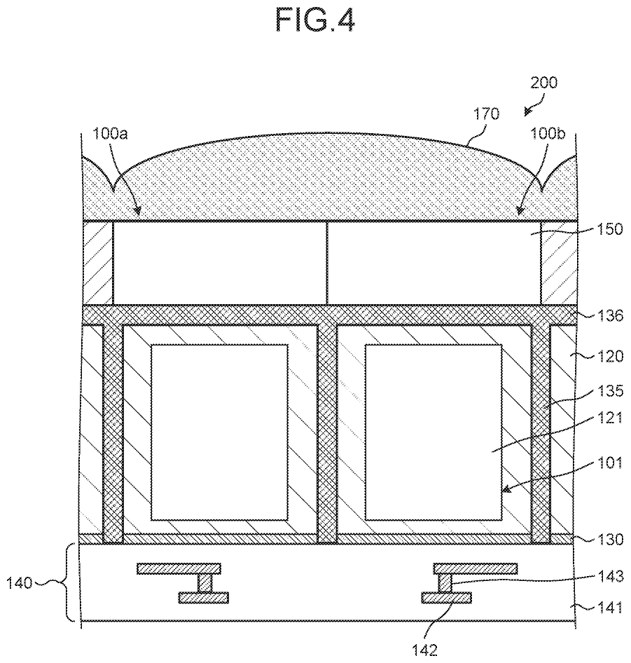

FIG. 4 is a cross-sectional view illustrating a configuration example of a pixel according to an embodiment of the present disclosure. The drawing is a cross-sectional view illustrating a configuration example of the pixel 100. In the drawing, a cross-sectional configuration of the pixel 100 will be described by taking the pixel 100a and the pixel 100b as an example. The pixel 100 includes a semiconductor substrate 120, an insulating film 130, a wiring region 140, an isolation portion 135, a protective film 136, and the color filter 150. Furthermore, the on-chip lenses 170 are commonly disposed in the pixels 100a and 100b.

The semiconductor substrate 120 is a semiconductor substrate on which the diffusion layer of the semiconductor element of the pixel 100 is disposed. The semiconductor substrate 120 can include, for example, silicon (Si). The semiconductor element and the like are disposed in a well region formed in the semiconductor substrate 120. For convenience, the semiconductor substrate 120 in the drawing is assumed to be formed in a p-type well region. A semiconductor element can be formed by disposing an n-type or p-type semiconductor region in the p-type well region. The photoelectric conversion unit 101 has been described as an example on the semiconductor substrate 120 in the drawing. The photoelectric conversion unit 101 includes an n-type semiconductor region 121. Specifically, a photodiode formed by a pn junction at an interface between the n-type semiconductor region 121 and a surrounding p-type well region corresponds to the photoelectric conversion unit 101.

The insulating film 130 is a film that insulates a front surface side of the semiconductor substrate 120.

For example, a film of silicon oxide (SiO₂) can be applied to the insulating film 130.

The wiring region 140 is a region that is disposed on the front surface side of the semiconductor substrate 120 and in which wiring of an element is formed. The wiring region 140 includes a wiring 141, a via plug 142, and an insulating layer 143. The wiring 141 is a conductor that transmits a signal to an element or the like of the semiconductor substrate 120. The wiring 141 can include, for example, a metal such as copper (Cu) or tungsten (W). The via plug 142 connects the wirings 141 disposed in different layers. The via plug 142 can include, for example, a columnar metal. The insulating layer 143 insulates the wiring 141 and the like. The insulating layer 143 can include, for example, SiO₂.

The isolation portion 135 is disposed at a boundary of the pixel 100 in the semiconductor substrate 120 to electrically and optically separate the pixel 100. The isolation portion 135 can include an insulator embedded in the semiconductor substrate 120. The isolation portion 135 can be formed, for example, by disposing an insulator such as SiO₂ in a groove portion penetrating the semiconductor substrate 120 formed at the boundary of the pixel 100.

The protective film 136 is a film that protects a back surface side of the semiconductor substrate 120. The protective film 136 can include an insulator such as SiO₂. The protective film 136 in the drawing can be formed simultaneously with the isolation portion 135.

The color filter 150 is an optical filter that transmits incident light having a predetermined wavelength among the incident light. As the color filter 150, for example, a color filter that transmits red light, green light, and blue light can be used. In this case, one color filter 150 corresponding to any of red light, green light, and blue light is disposed in the pixel 100. The pixel 100 generates an image signal of incident light having a wavelength corresponding to the color filter 150. As described above, color filters 150 of the same type are disposed in the plurality of pixels 100 disposed in the pixel block 200. Further, the color filter 150 in the drawing is disposed on the back surface side of the semiconductor substrate 120.

The on-chip lens 170 is a lens commonly disposed in the plurality of pixels 100 constituting the pixel block 200 as described above. The on-chip lens 170 in the drawing is formed in a hemispherical cross section and condenses incident light on the photoelectric conversion unit 101. The on-chip lens 170 can include an organic material such as an acrylic resin or an inorganic material such as silicon nitride (SiN).

### [Configuration of Column Signal Processing Unit]

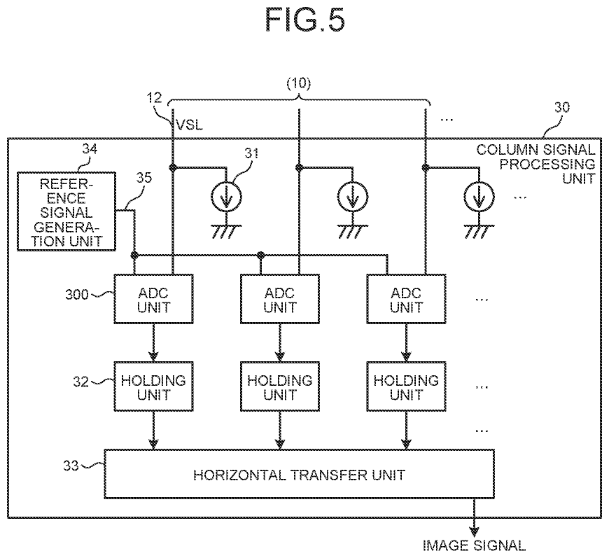

FIG. 5 is a diagram illustrating a configuration example of a column signal processing unit according to the embodiment of the present disclosure. The drawing is a diagram illustrating a configuration example of the column signal processing unit 30. The column signal processing unit 30 includes a constant current circuit 31, an analog-to-digital conversion (ADC) unit 300, a holding unit 32, a horizontal transfer unit 33, and a reference signal generation unit 34. Among these, the constant current circuit 31, the analog-to-digital conversion unit 300, and the holding unit 32 are disposed for each of the plurality of signal lines 12.

The constant current circuit 31 is a circuit constituting a load of the amplification transistor 111 described in FIG. 3. A sink side terminal of the constant current circuit 31 is connected to the signal line 12, and a source side terminal is grounded. Thus, the constant current circuit 31 constitutes a source follower circuit together with the amplification transistor 111. The image signal is transmitted as a signal of a voltage corresponding to the incident light to the signal line 12 to which the sink side terminal of the constant current circuit 31 is connected.

The reference signal generation unit 34 generates a reference signal and outputs the reference signal to the analog-to-digital conversion unit 300. This reference signal is a signal whose value changes in a ramp function manner.

The analog-to-digital conversion unit 300 performs analog-to-digital conversion of an image signal. The analog-to-digital conversion unit 300 converts an analog image signal generated by the pixel 100 into a digital image signal. The analog-to-digital conversion unit 300 in the drawing converts an analog image signal into a digital image signal on the basis of the reference signal output from the reference signal generation unit 34. Specifically, the analog-to-digital conversion unit 300 compares the analog image signal with the reference signal, and detects a period until the analog image signal matches with the reference signal. Since the reference signal is a signal of a voltage corresponding to the elapsed time, the period from the start of output of the reference signal until the reference signal coincides with the analog image signal is a period corresponding to the voltage of the analog image signal. By outputting a digital signal corresponding to this period, an analog image signal can be converted into a digital image signal.

The holding unit 32 holds an image signal converted into a digital signal by the analog-to-digital conversion unit 300. Furthermore, the holding unit 32 can perform correlated double sampling (CDS). This CDS is processing of removing an offset (noise) by obtaining a difference of the image signal at the time of the above-described reset from the image signal generated by exposure. Charges that are not discharged in the reset remain in the charge holding unit 103 and the like described in FIG. 3. A signal component based on the remaining charges becomes an offset component of the image signal and causes noise. Accordingly, it is possible to remove the offset component by holding the image signal at the time of reset and subtracting the image signal at the time of reset (image signal at a reset level) from the image signal (image signal at a signal level) based on the charge generated and transferred at the time of exposure. The holding unit 32 in the drawing can hold the image signal at the time of reset and perform processing of subtracting the reset level from the signal level. By performing this CDS, noise of the image signal can be reduced.

The horizontal transfer unit 44 transfers an image signal. Outputs of all the holding units 32 disposed for each signal line 12 are connected to the horizontal transfer unit 44 in the drawing. The horizontal transfer unit 44 sequentially transfers and outputs the image signal output from the holding unit 32. For example, the horizontal transfer unit 44 can sequentially transfer and output the image signal from the holding unit 32 at the right end among the plurality of holding units 32 disposed in the column signal processing unit 30 in the drawing.

### [Generation of Image Signal]

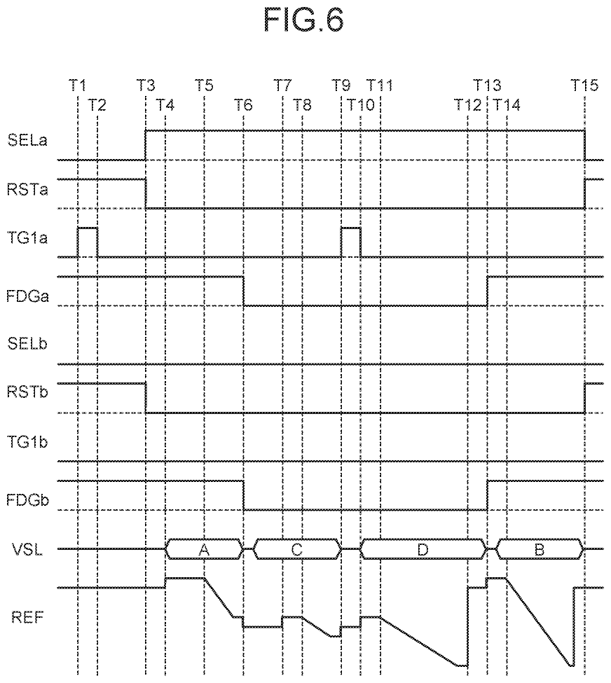

FIG. 6 is a diagram illustrating an example of generation of an image signal according to the first embodiment of the present disclosure. The drawing is a timing chart illustrating an example of generation of an image signal in the pixel block 200. Furthermore, the drawing illustrates an example in a case where an image signal based on charges of the pixel 100a (the photoelectric conversion unit 101a and the charge transfer unit 102a) of the pixel block 200a is generated. Generation of the image signal in the pixel block 200 will be described with reference to the drawing as an example.

“SELa”, “RSTa”, “TG1a”, and “FDGa” in the drawing represent signals of the signal line SEL, the signal line RST, the signal line TG1, and the signal line FDG in the pixel block 200a. Furthermore, “SELb”, “RSTb”, “TG1b”, and “FDGb” represent signals of the signal line SEL, the signal line RST, the signal line TG1, and the signal line FDG in the pixel block 200b. “VSL” represents an image signal output to the signal line VSL. “REF” represents the waveform of the reference signal output from the reference signal generation unit 34 described in FIG. 5.

In the signals of “SELa”, “RSTa”, “TG1a”, “FDGa”, “SELb”, “RSTb”, “TG1b”, and “FDGb”, “TG1”, “TG2”, “TG3”, and “TG4”, a portion of a value “1” of the binarized waveform represents the on-voltage (Von). As the on-voltage, for example, a voltage of 3 V can be applied. In addition, a portion of a value “0” represents the off-voltage. A broken line in the drawing represents the level of the off-voltage. For example, 0 V or a negative voltage (For example, −1.2 V) can be applied as the off-voltage.

In the initial state, the off-voltage is input to the signal lines SELa and SELb and the signal lines TG1a and TG1b. In addition, the on-voltage is input to the signal lines RSTa and RSTb and the signal lines FDGa and FDGb. Since the reset unit 104 and the coupling unit 107 are brought into a conductive state, the charge holding unit 103 and the auxiliary charge holding unit 108 are reset.

At T1, the on-voltage is input from the signal line TG1. Thus, the charge transfer unit 102a is brought into a conductive state in addition to the reset unit 104, and the photoelectric conversion unit 101a is reset in addition to the charge holding unit 103 and the auxiliary charge holding unit 108.

At T2, the input of the on-voltage of the signal line TG1 is stopped. Thus, an exposure period is started. Charges generated by photoelectric conversion in the photoelectric conversion unit 101a are accumulated.

At T3, the on-voltage is input from the signal line SEL. Thus, the pixel block 200a is selected. In addition, the input of the on-voltages of the reset signal lines RSTa and RSTb is stopped. Thus, resetting of the charge holding unit 103 and the auxiliary charge holding unit 108 is stopped.

At T4, the image signal generation unit 110 of the pixel block 200a starts outputting an image signal at the time of reset. “A” of the signal line VSL in the drawing represents an image signal at the reset level. Note that, since the on-voltage is input to the signal line FDGa and the coupling unit 107 is in a conductive state, “A” is the image signal at the reset level in the low sensitivity mode.

In the period from T5 to T6, the reference signal generation unit 34 outputs a ramp function-shaped reference signal, and the analog-to-digital conversion unit 300 performs analog-to-digital conversion. The conversion result becomes a digital image signal at a reset level in the low sensitivity mode, and is held in the holding unit 32.

At T6, the input of the on-voltage to the signal lines FDGa and FDGb is stopped. Thus, the coupling unit 107 is brought into a non-conductive state and shifts to the high sensitivity mode. Furthermore, in the period from T6 to T7, the image signal generation unit 110 of the pixel block 200a starts outputting the image signal at the time of reset. “C” of the signal line VSL in the drawing represents an image signal at the reset level in the high sensitivity mode.

In the period from T8 to T9, the reference signal generation unit 34 outputs the reference signal, and the analog-to-digital conversion unit 300 performs analog-to-digital conversion. The conversion result becomes a digital image signal at the reset level in the high sensitivity mode, and is held in the holding unit 32.

At T9, the on-voltage is input from the signal line TG1a, and the charge transfer unit 102a is brought into a conductive state. Thus, the charge accumulated in the photoelectric conversion unit 101a is transferred to the charge holding unit 103.

At T10, the input of the on-voltage of the signal line TG1a is stopped, and the charge transfer unit 102a is brought into a non-conductive state. In the period from T10 to T11, the image signal generation unit 110 generates the image signal “D” and outputs the image signal “D” to the signal line VSL. This image signal corresponds to an image signal at the signal level based on the electric charge of the photoelectric conversion unit 101a.

In the period from T11 to T12, the reference signal generation unit 34 outputs the reference signal, and the analog-to-digital conversion unit 300 performs analog-to-digital conversion. The conversion result becomes a digital image signal at the signal level in the high sensitivity mode, and is held in the holding unit 32. The CDS can be performed by subtracting the digital image signal at the reset level (corresponding to the value C) from the digital image signal at the signal level (corresponding to the value D).

At T13, the on-voltage is input to the signal lines FDGa and FDGb. Thus, the coupling unit 107 is brought into a conductive state and shifts to the low sensitivity mode. In addition, in the period from T13 to T14, the image signal generation unit 110 of the pixel block 200a generates the image signal “B” and outputs the image signal “B” to the signal line VSL. This image signal corresponds to an image signal at the signal level in the low sensitivity mode.

In the period from T14 to T15, the reference signal generation unit 34 outputs the reference signal, and the analog-to-digital conversion unit 300 performs analog-to-digital conversion. The conversion result becomes a digital image signal at the signal level in the low sensitivity mode, and is held in the holding unit 32. The CDS can be performed by subtracting the digital image signal at the reset level (corresponding to the value A) from the digital image signal at the signal level (corresponding to the value B).

At T15, the application of the on-voltage of the signal line SELa is stopped, and the pixel block 200a is brought into a non-selected state. Further, a value “1” is input to the signal lines RSTa and RSTb. Thus, the state returns to the initial state, and resetting of the charge holding unit 103 and the auxiliary charge holding unit 108 is resumed.

According to the above procedure, an image signal can be generated in the pixel block 200a. Note that the period from T2 to T9 corresponds to the exposure period.

As described above, the on-voltage is input to the signal line FDG and the signal line RST in a period in which the pixel blocks 200a and 200b are not selected, that is, in a charge non-holding period, and the reset unit 104 and the coupling unit 107 are brought into a conductive state. It is possible to secure a longer reset period than a conventional reset period (for example, a period from T3 to T4 in the drawing).

### [Another Configuration of Imaging Element]

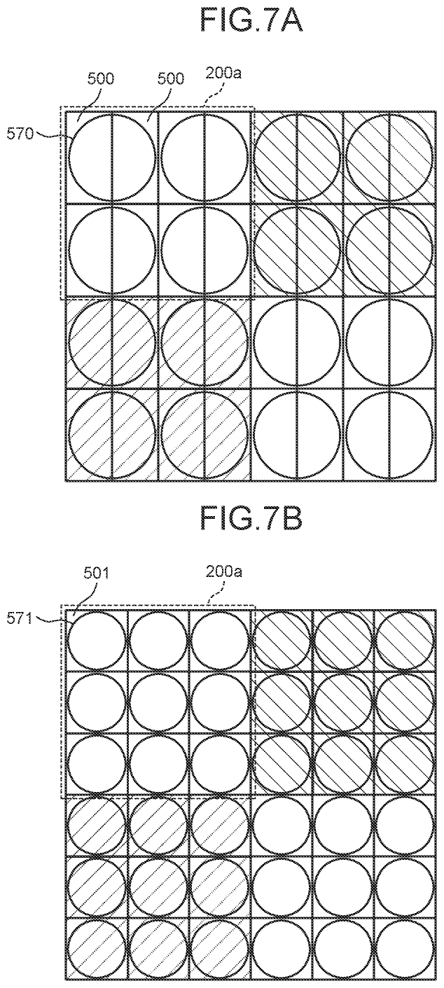

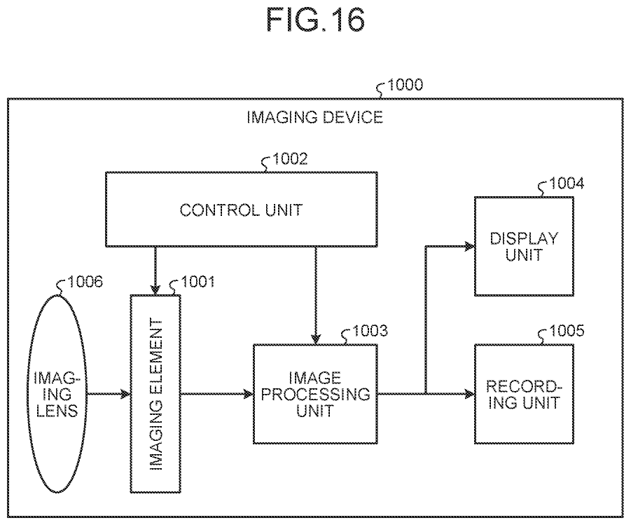

FIGS. 7A and 7B are diagrams illustrating another configuration example of the imaging element according to the first embodiment of the present disclosure. FIG. 16A is a diagram illustrating an example of the pixel block 200a configured by arranging rectangular pixels 500. An on-chip lens 570 is commonly disposed in the two pixels 500. The two pixels 500 can generate a phase difference signal that pupil-divides a subject in the left-right direction in the drawing. The pixel block 200a in the drawing represents an example in which eight pixels 500 are disposed.

FIG. 16B is a diagram illustrating an example of the pixel block 200a configured by arranging a pixels 501 including the on-chip lens 571 in three rows and three columns. The pixel block 200a in the drawing represents an example in which nine pixels 500 are disposed.

As described above, the imaging element 1 according to the first embodiment of the present disclosure resets the auxiliary charge holding unit 108 by making the reset unit 104 and the coupling unit 107 conductive in a period in which the pixel blocks 200a and 200b are not selected, that is, in a charge non-holding period. Thus, a relatively long reset period can be secured, the charge remaining in the auxiliary charge holding unit 108 can be reduced, and errors of the image signal in the low sensitivity mode can be reduced. In addition, a decrease in the frame frequency can be prevented.

### 2. Second Embodiment

The imaging element 1 according to the first embodiment described above inputs the off-voltage to the signal line FDG in the high sensitivity mode, whereas the imaging element 1 according to a second embodiment of the present disclosure differs from the imaging element 1 according to the first embodiment described above in that a middle voltage between the on-voltage and the off-voltage is input.

### [Generation of Image Signal]

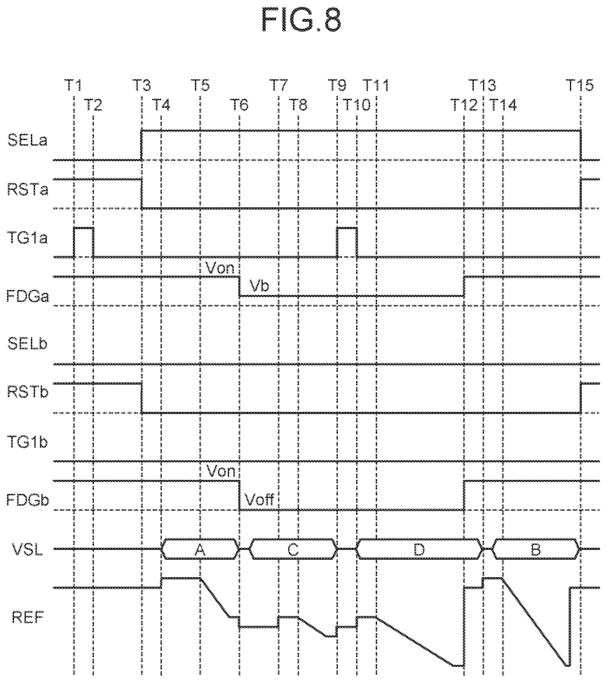

FIG. 8 is a diagram illustrating an example of generation of an image signal according to the second embodiment of the present disclosure. The drawing is a timing chart illustrating an example of generation of an image signal in the pixel block 200, similarly to FIG. 6. This drawing is different from FIG. 6 in that a middle voltage (Vb) between an on-voltage (Von) and an off-voltage (Voff) is input to the signal line FDGa. Here, as the middle voltage, for example, a voltage of 0.5 V can be employed in a case where the on-voltage and the off-voltage are 3.3 V and 0 V, respectively.

In the drawing, Vb is input to the signal line FDGa in a period from T6 to T12. Thus, the coupling unit 107 is turned on with a relatively high resistance during this period. Thus, the potential of the coupling unit 107 can be adjusted in the high sensitivity mode in the selected pixel block 200a.

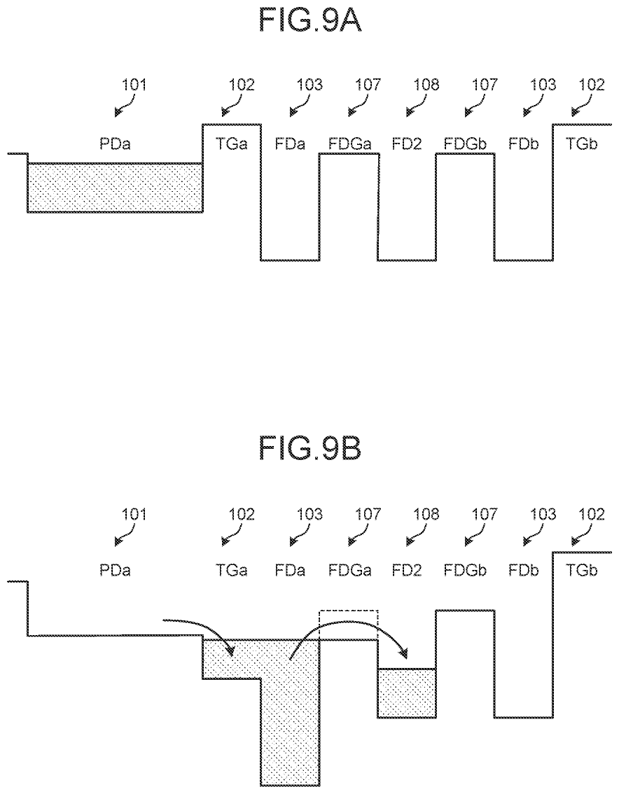

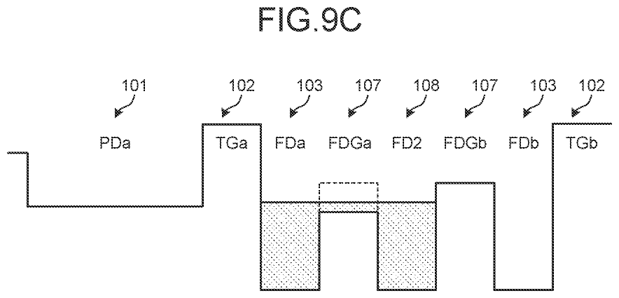

In a period from T9 to T10 in the drawing, the charge of the photoelectric conversion unit 101a is transferred to the charge holding unit 103. At this time, in a case where a large amount of charge is accumulated in the photoelectric conversion unit 101a, an excessive charge overflows from the charge holding unit 103. By applying Vb to the MOS transistor of the coupling unit 107 to adjust the potential, overflowing charges can be moved to the auxiliary charge holding unit 108. This state will be described with reference to FIG. 9.

### [Transfer of Charge]

FIGS. 9A to 9C are diagrams illustrating examples of charge transfer according to the second embodiment of the present disclosure. The drawings are diagrams illustrating potentials of the photoelectric conversion unit 101a, the charge transfer unit 102a, the charge holding unit 103 and the coupling unit 107 of the pixel block 200a, the auxiliary charge holding unit 108, the coupling unit 107 and the charge holding unit 103 of the pixel block 200b, and the charge transfer unit 102b. In the potential in the drawing, the lower side corresponds to a high potential, and the upper side corresponds to a low potential. “PDa”, “TGa”, “FDa”, and “FDGa” in the drawing represent the photoelectric conversion unit 101a, the charge transfer unit 102a, the charge holding unit 103, and the coupling unit 107 of the pixel block 200a. Further, “FD2” represents the auxiliary charge holding unit 108. Furthermore, “FDGb”, “FDb”, and “TGb” represent the coupling unit 107, the charge holding unit 103, and the charge transfer unit 102b of the pixel block 200b.

FIG. 9A illustrates a state in which charges are accumulated in the photoelectric conversion unit 101a. A dot-hatched region in the drawing represents a charge. This drawing corresponds to the state T3 in FIG. 8.

FIG. 9B illustrates a state in which the charge transfer unit 102a is brought into a conductive state, and the charge of the photoelectric conversion unit 101a is transferred to the charge holding unit 103a. This drawing corresponds to the states from T9 to T10 in FIG. 8. As the potential of the charge transfer unit 102a becomes deeper, the potential of the charge holding unit 103 also becomes deeper. This is because the charge holding unit 103 is capacitively coupled to the gate of the charge transfer unit 102a. Thus, the charge of the photoelectric conversion unit 101a is transferred to the charge holding unit 103. At this time, Vb is applied to the coupling unit 107 via the signal line FDG, and the potential of the coupling unit 107 is adjusted and deepened. A dotted line in the drawing represents a potential in a case where Voff is applied. Thus, the charge overflowing from the charge holding unit 103 moves to the auxiliary charge holding unit 108 via the coupling unit 107.

FIG. 9C illustrates a state in which the charge transfer unit 102a is non-conductive. This drawing corresponds to the state of T10 in FIG. 8.

When the charge of the photoelectric conversion unit 101a is transferred, by adjusting the potential of the coupling unit 107, the charge overflowing from the charge holding unit 103 can be moved to the auxiliary charge holding unit 108. Thus, the overflowed charge can be prevented from moving to another pixel 100 or the like. Furthermore, by deeply adjusting the potential of the coupling unit 107, all the charges accumulated in the photoelectric conversion unit 101a can be transferred at one time.

### [Comparative Example of Charge Transfer]

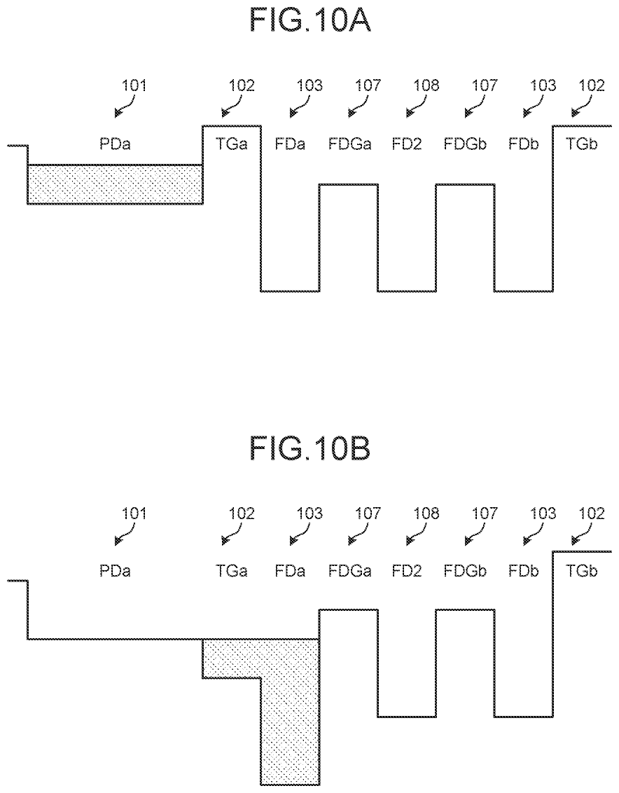

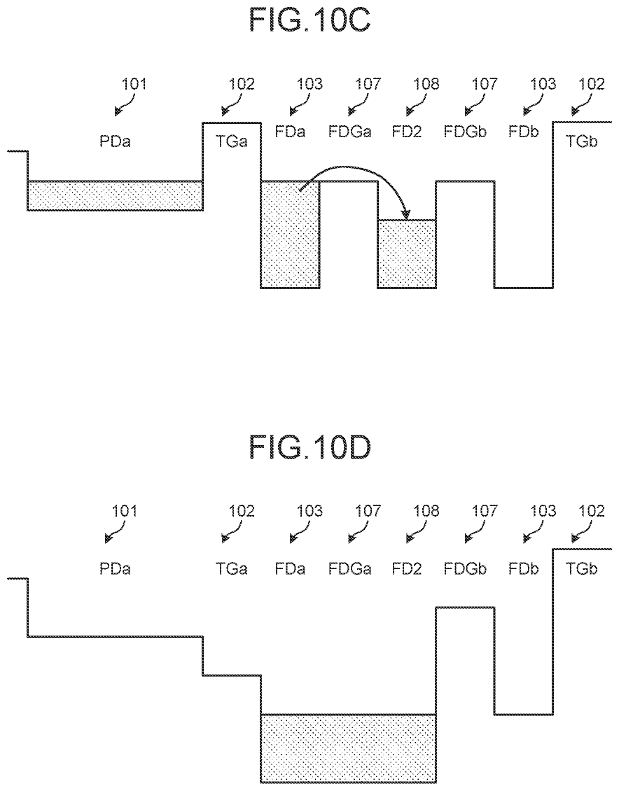

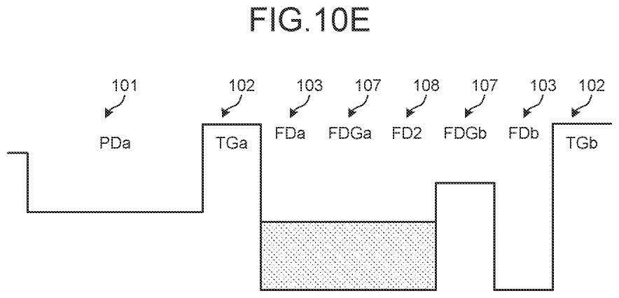

FIGS. 10A to 10E are diagrams illustrating an example of charge transfer according to a conventional embodiment. The drawings are potential diagrams represented as a comparative example. Similarly to FIG. 9A, FIG. 10A illustrates a state in which charges are accumulated in the photoelectric conversion unit 101a.

FIG. 10B illustrates a state in which the charge transfer unit 102a is brought into a conductive state, and the charge of the photoelectric conversion unit 101a is transferred to the charge holding unit 103a. Unlike FIG. 9B, the coupling unit 107 is in a conductive state, and the potential becomes shallow.

FIG. 10C illustrates a state in which the charge transfer unit 102a returns to the non-conductive state. The electric charge overflows from the charge holding unit 103, and a part of the electric charge moves to the auxiliary charge holding unit 108. At this time, depending on the arrangement of the coupling unit 107, the overflowed charge may move to the charge holding unit 103 of the pixel block 200b. In addition, a part of the overflowed charge remains in the photoelectric conversion unit 101a.

FIG. 10D illustrates a state in which the charge transfer unit 102a and the coupling unit 107 are conducted. Thus, the residual charge of the photoelectric conversion unit 101a can be transferred to the charge holding unit 103 and the auxiliary charge holding unit 108.

FIG. 10E illustrates a state in which the charge transfer unit 102a returns to the non-conductive state. As described above, in the conventional charge transfer method, it is difficult to collect the charge overflowing from the charge holding unit 103. In addition, it is necessary to transfer the charge of the photoelectric conversion unit 101a twice.

The configuration of the imaging element 1 other than this is similar to the configuration of the imaging element 1 in the first embodiment of the present disclosure, and thus description thereof is omitted.

As described above, the imaging element 1 according to the second embodiment of the present disclosure applies a middle voltage to the gate of the MOS transistor constituting the coupling unit 107 when transferring the charge to the charge holding unit 103 of the own pixel block 200 in the high sensitivity mode. Thus, the potential of the coupling unit 107 can be adjusted, and the charge overflowing from the charge holding unit 103 can be moved to the auxiliary charge holding unit 108. Thus, it is possible to prevent occurrence of an error of the image signal due to mixture of the overflowed charge. In addition, the charge of the photoelectric conversion unit 101 can be transferred by one transfer, and the amount of charge remaining in the photoelectric conversion unit 101 can be reduced. Thus, the time required for generating the image signal can be shortened.

### 3. Third Embodiment

The imaging element 1 of the first embodiment described above individually transfers the charge of the pixel 100 of the pixel block 200. On the other hand, an imaging element 1 according to a third embodiment of the present disclosure is different from the above-described first embodiment in that the imaging element 1 includes a mode for simultaneously transferring charges of the pixels 100 disposed in the pixel block 200 to generate a pixel signal.

### [Configuration of Pixel Block]

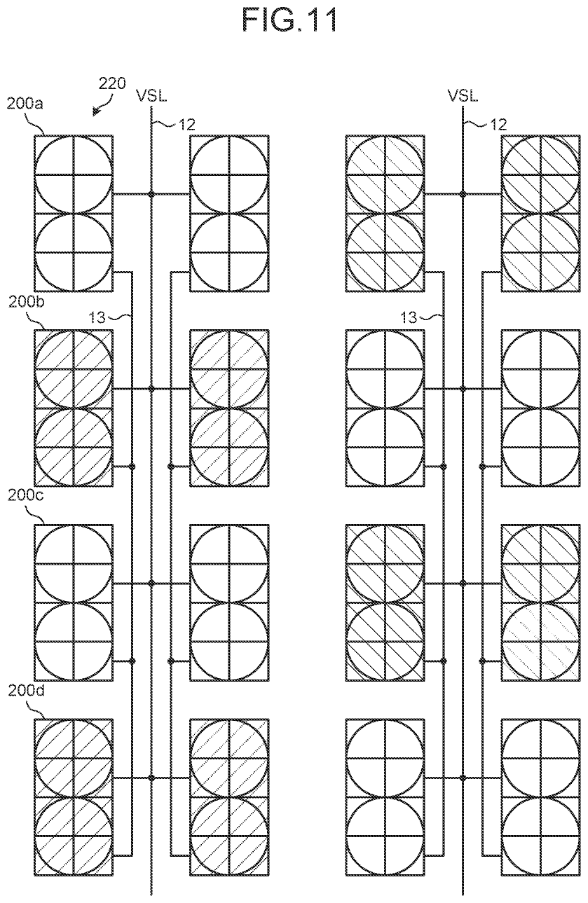

FIG. 11 is a diagram illustrating a configuration example of a pixel block according to the third embodiment of the present disclosure. The drawing is a block diagram illustrating a configuration example of the pixel block 200 similarly to FIG. 2. The pixel block 200 in the drawing is different from the pixel block 200 in FIG. 2 in that eight pixels 100 are disposed. A rectangle in the drawing represents a pixel 100.

In the pixel block 200 in the drawing, two sets of four pixels 100 arrayed in two rows and two columns in which the on-chip lens 170 is commonly disposed are disposed. In addition, four pixel blocks 200 (pixel blocks 200a, 200b, 200c, and 200d) are commonly connected to the signal line 13 and the signal line 12 described in FIG. 3. These four pixel blocks 200 constitute a pixel block unit 220. The pixel block units 220 are arrayed in the pixel array unit 10 in a two-dimensional matrix. Note that, similarly to the pixel block 200 in FIG. 2, the pixels 100 in the drawing can generate a phase difference signal.

### [Circuit Configuration of Pixel Block]

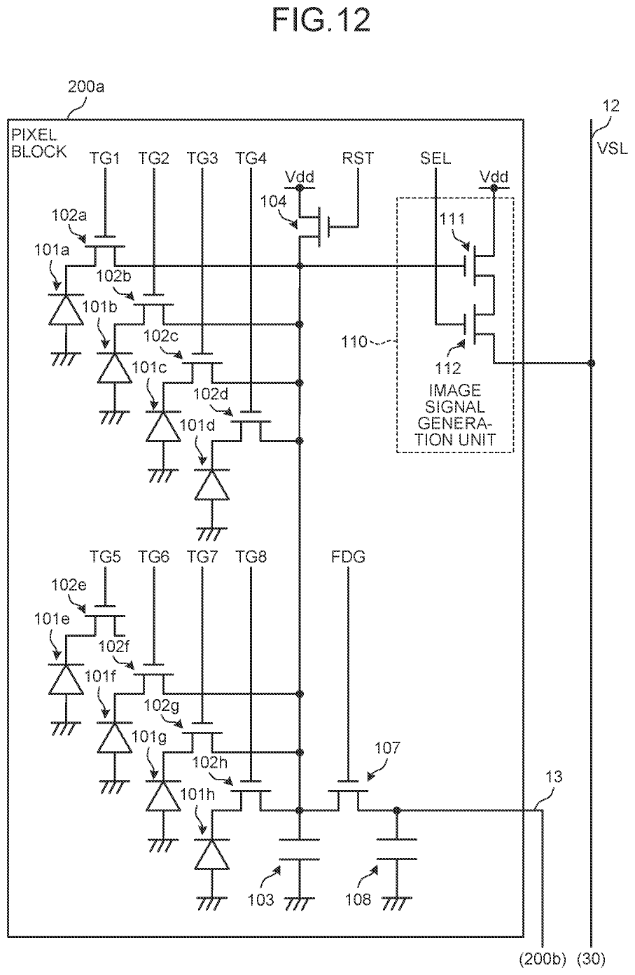

FIG. 12 is a diagram illustrating an example of a circuit configuration of a pixel block according to the third embodiment of the present disclosure. The drawing is a circuit diagram illustrating a configuration example of the pixel block 200a. The pixel block 200a in the drawing is obtained by adding photoelectric conversion units 101e, 101f, 101g, and 101h and charge transfer units 102e, 102f, 102g, and 102h to the pixel block 200a in FIG. 3. Note that a signal line TG5, a signal line TG6, a signal line TG7, and a signal line TG8 are respectively wired to gates of the charge transfer units 102e, 102f, 102g, and 102h.

The pixel block 200 in the drawing can generate an image signal in a low resolution mode in addition to a high resolution mode in which charges of the photoelectric conversion unit 101a and the like are individually transferred to generate an image signal. This low resolution mode is an operation mode in which charges of all the photoelectric conversion units, that is, the photoelectric conversion units 101a to 101h are simultaneously transferred to the charge holding unit 103 to generate an image signal. In each of the high resolution mode and the high resolution mode, an image signal can be generated in the high sensitivity mode and the low sensitivity mode.

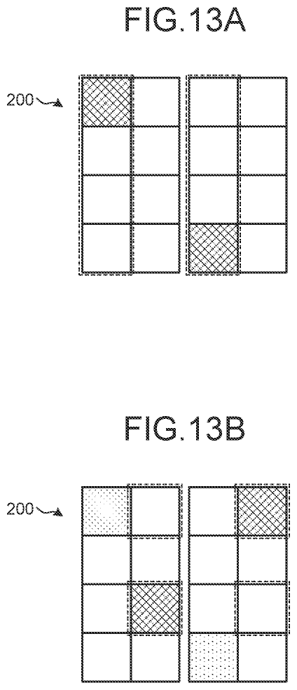

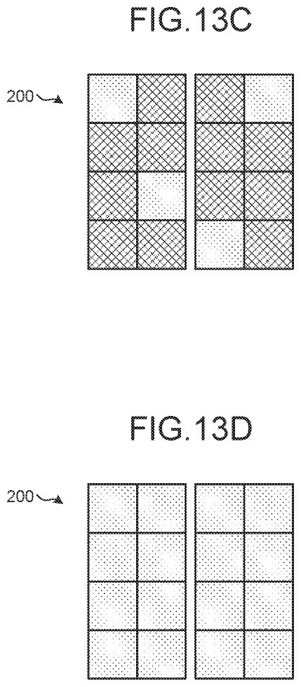

Also for the phase difference signal, the phase difference signals in the high sensitivity mode and the low sensitivity mode can be generated in the low resolution mode. Generation of the phase difference signal will be described with reference to FIGS. 13A to 13D.

### [Generation of Phase Difference Signal]

FIGS. 13A to 13D are diagrams illustrating an example of generation of a phase difference signal according to the third embodiment of the present disclosure. The drawing is a diagram illustrating an example of generation of a phase difference signal in the pixel block 200a. As described above, the pixel block 200 includes the pixels 100 disposed in four rows and two columns, and can divide the pupil of the subject in the left-right direction and the up-down direction. A dotted region in FIG. 13A represents the pixel 100 that generates a left-side phase difference signal in a case of pupil division in the left-right direction. In this manner, the image signals of the four pixels 100 on the left side are added to generate the phase difference signal in the left-right direction in the low resolution mode. Furthermore, a dotted region in FIG. 13B represents a pixel 100 that generates an upper (upper right) phase difference pixel in a case where pupil division is performed in the up-down direction. In this manner, an upper phase difference signal is generated by adding image signals of any one pixel 100 of the two pixels 100 sharing the on-chip lens 170. The phase difference signal when pupil division is performed in the up-down direction is at a level of 50% of the phase difference signal when pupil division is performed in the left-right direction.

In the present embodiment, the generation of the phase difference signal in the low resolution mode is proposed. By sequentially performing four image signal generation modes in FIGS. 13A to 13D, the phase difference signal, the image signal in the high sensitivity mode, and the image signal in the low resolution mode are generated. Note that, in the present embodiment, the conversion ratio in the high sensitivity mode and the low sensitivity mode is assumed to be 4:1.

In FIG. 13A, charges of the photoelectric conversion unit of the pixel 100 shaded with hatching in the same drawing are transferred to the charge holding unit 103 to generate an image signal. The pixel 100 is one pixel 100 among the pixels 100 disposed on the left side when pupil division is performed in the left-right direction. This operation mode is referred to as a first image signal generation mode. Further, the generated image signal is referred to as a first image signal.

In FIG. 13B, charges of the photoelectric conversion unit of the pixel 100 shaded with hatching in the drawing are further transferred to the charge holding unit 103 to generate an image signal. The pixel 100 is one pixel 100 among the pixels 100 disposed on the upper side (upper right side) when pupil division is performed in the up-down direction. Note that a dot-hatched region in the drawing represents the pixel 100 to which charge is transferred in the previous image signal generation mode. This operation mode is referred to as a second image signal generation mode. Further, the generated image signal is referred to as a second image signal.

In FIG. 13C, charges of the photoelectric conversion units of the pixels 100 shaded with hatching in the drawing are further transferred to the charge holding unit 103 to generate an image signal. The pixels 100 are the remaining pixels 100 that have not been charged in the first image signal generation mode and the second image signal generation mode. Thus, an image signal in the high sensitivity mode in the low resolution mode can be generated. This operation mode is referred to as a third image signal generation mode. Further, the generated image signal is referred to as a third image signal.

FIG. 13D illustrates an operation mode in which the image signal is generated again after the coupling unit 107 is made conductive to shift to the low sensitivity mode. Thus, an image signal in the low sensitivity mode in the low resolution mode can be generated. This operation mode is referred to as a fourth image signal generation mode. Further, the generated image signal is referred to as a fourth image signal. Thereafter, the phase difference signal is generated by mutual calculation of the first image signal to the fourth image signal.

The first image signal corresponds to the left-side phase difference signal in the low sensitivity mode. This is because the conversion ratio in the high sensitivity mode and the low sensitivity mode is 4:1.

Next, the first image signal is subtracted from the fourth image signal. Thus, a right-side phase difference signal in the low sensitivity mode can be generated.

Next, the first image signal is subtracted from the second image signal. Further, by dividing the calculation result by a value “2”, the upper (upper right) phase difference signal in the low sensitivity mode can be generated.

Next, the first image signal is subtracted from the fourth image signal, and a value obtained by dividing the second image signal by a value “2” is further subtracted. Thus, a lower (lower right) phase difference signal in the low sensitivity mode can be generated. Note that the upper and lower phase difference signals are an example of a second phase difference signal described in the claims.

Note that the right and left phase difference signals in the high sensitivity mode can be generated by multiplying the right and left phase difference signals in the low sensitivity mode by a value “4”.

As described above, the pixel block 200 of the present embodiment can generate the phase difference signal in addition to the image signals of the high sensitivity mode and the low sensitivity mode in the low sensitivity mode in one image signal generation period. Next, the analog-to-digital conversion unit 300 that can be used to generate the image signal will be described.

### [Configuration of Analog-to-Digital Conversion Unit]

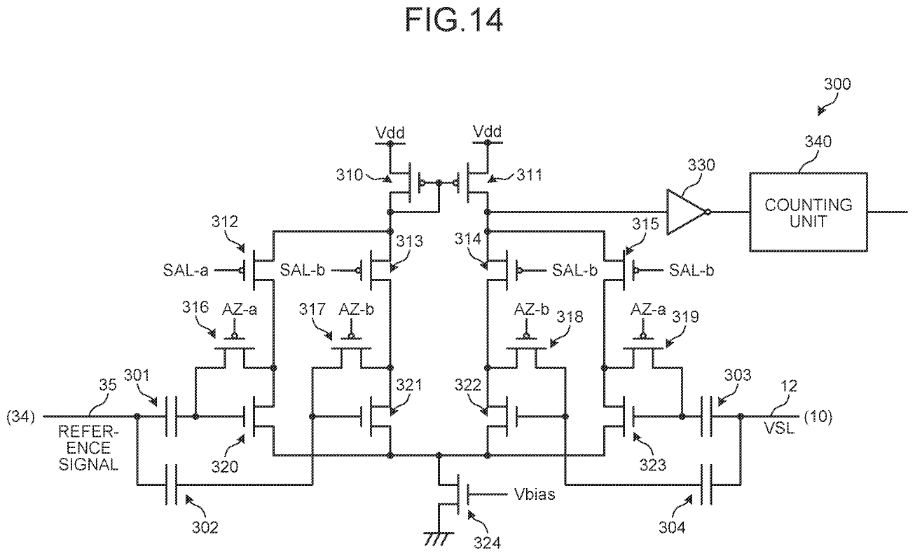

FIG. 14 is a diagram illustrating a configuration example of an analog-to-digital conversion unit according to the third embodiment of the present disclosure. The drawing is a circuit diagram illustrating a configuration example of the analog-to-digital conversion unit 300. The analog-to-digital conversion unit 300 in the drawing includes capacitors 301 to 304, MOS transistors 310 to 323, an inversion buffer 330, and a counting unit 340. As the MOS transistors 310 to 319, p-channel MOS transistors can be used. Furthermore, n-channel MOS transistors can be used as the MOS transistors 320 to 323.

A signal line 35 from the reference signal generation unit 34 is connected to a gate of the MOS transistor 320 via the capacitor 301 and is connected to a gate of the MOS transistor 321 via the capacitor 302. A drain of the MOS transistor 316 is connected to the gate of the MOS transistor 320, and a source of the MOS transistor 316 is connected to a source of the MOS transistor 320 and a drain of the MOS transistor 312. A drain of the MOS transistor 317 is connected to the gate of the MOS transistor 321, and a source of the MOS transistor 317 is connected to a source of the MOS transistor 321 and a drain of the MOS transistor 313. A source of the MOS transistor 312 is connected to a source of the MOS transistor 313, a drain of the MOS transistor 310, a gate of the MOS transistor 310, and a gate of the MOS transistor 311. A source of the MOS transistor 310 and a source of the MOS transistor 311 are commonly connected to the power supply line Vdd.

The signal line 12 from the pixel array unit 10 is connected to a gate of the MOS transistor 323 via the capacitor 303 and is connected to a gate of the MOS transistor 322 via the capacitor 304. A drain of the MOS transistor 319 is connected to the gate of the MOS transistor 323, and a source of the MOS transistor 319 is connected to a source of the MOS transistor 323 and a drain of the MOS transistor 315. A drain of the MOS transistor 318 is connected to the gate of the MOS transistor 322, and a source of the MOS transistor 318 is connected to a source of the MOS transistor 322 and a drain of the MOS transistor 314. A source of the MOS transistor 315 is connected to a source of the MOS transistor 314, a drain of the MOS transistor 311, and an input terminal of the inversion buffer 330.

The source of the MOS transistor 320, the source of the MOS transistor 321, the source of the MOS transistor 322, and the source of the MOS transistor 323 are commonly connected to a drain of the MOS transistor 324. A source of the MOS transistor 324 is grounded, and a gate is connected to the signal line Vbias. A gate of the MOS transistor 312 is connected to a signal line SAL-a. A gate of the MOS transistor 313 is connected to a signal line SAL-b. A gate of the MOS transistor 314 is connected to the signal line SAL-b. A gate of the MOS transistor 315 is connected to the signal line SAL-b. A gate of the MOS transistor 316 is connected to a signal line AZ-a. A gate of the MOS transistor 317 is connected to a signal line AZ-b. A gate of the MOS transistor 318 is connected to the signal line AZ-b. A gate of the MOS transistor 319 is connected to the signal line AZ-a. An output terminal of the inversion buffer 330 is connected to the counting unit 340.

The MOS transistors 320 and 323 and the MOS transistors 321 and 322 form a differential pair. These differential pairs can be switched by the MOS transistors 312 to 315. The MOS transistor 324 is a circuit that supplies a constant current to these differential pairs. Further, the MOS transistors 310 and 311 constituting a current mirror circuit constitute drain loads of these differential pairs. The MOS transistors 316 to 319 are MOS transistors that reset the differential pair. The differential pairs compare the reference signal and the image signal transmitted by the signal line 12. Results of the comparison are input to the counting unit 340 via the inversion buffer 330.

The analog-to-digital conversion unit 300 in the drawing can continuously compare the image signal and the reference signal by switching the MOS transistors 320 and 323 and the MOS transistors 321 and 322 which are two differential pairs.

The counting unit 340 counts a period during which the reference signal is equal to the image signal. The counting unit 340 performs counting on the basis of a clock signal (not illustrated). This count is a period from the start of generation of the reference signal to the timing at which the reference signal detected by the differential pair becomes equal to the image signal. Furthermore, the counting unit 340 can subtract the image signal at the reset level from the image signal at the signal level. Specifically, the counting unit 340 performs down counting when generating an image signal at the reset level, and performs up counting from a down count value when generating an image signal at the signal level. Thus, the image signal at the reset level can be subtracted, and the CDS can be performed. Note that the counting unit 340 is an example of an image signal correction unit described in the claims.

Note that the capacitors 301 to 304 are coupling capacitors. The capacitors 301 to 304 hold offset components at the time of resetting the differential pair. Thus, the error of the analog-to-digital conversion unit 300 can be reduced.

Note that the CDS processing may be performed by the holding unit 32 described in FIG. 5. In this case, the holding unit 32 is an example of an image signal correction unit described in the claims.

### [Generation of Image Signal]

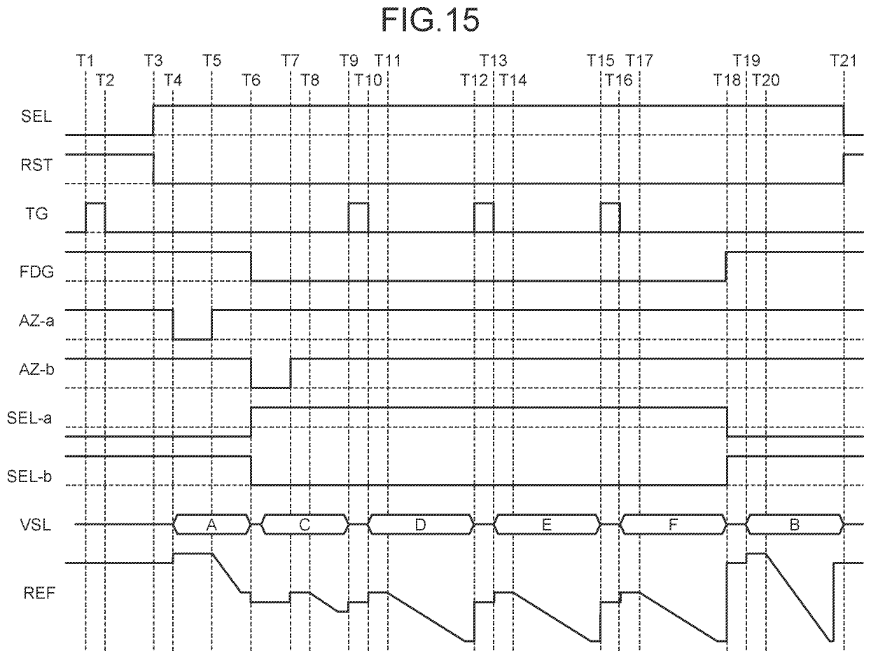

FIG. 15 is a diagram illustrating an example of generation of an image signal according to the third embodiment of the present disclosure. The drawing is a timing chart illustrating an example of generation of an image signal in the pixel block 200, similarly to FIG. 6. Furthermore, the drawing illustrates an example in a case where an image signal based on charges of the pixel 100a (the photoelectric conversion unit 101a and the charge transfer unit 102a) of the pixel block 200a is generated. Generation of the image signal in the pixel block 200 will be described with reference to the drawing as an example.

“SEL”, “RST”, and “FDG” in the drawing represent signals of the signal line SEL, the signal line RST, and the signal line FDG in the pixel block 200a. Further, “TG” in the drawing represents signals of the signal lines TG1 to TG8. “AZ-a”, “AZ-b”, “SEL-a”, and “SEL-b” represent the control signals of the signal line AZ-a, the signal line AZ-b, the signal line SEL-a, and the signal line SEL-b described in FIG. 14. Other notations common to FIG. 6 are used.

In the initial state, a value “0” is input to the signal line SEL, the signal line TG1, and the signal line SEL-a. Further, a value “1” is input to the signal line RST, the signal line FDG, and the signal line SEL-b.

At T1, an on-voltage is input to the signal lines TG1 to TG8. Thus, the charge transfer units 102a to 102h are brought into a conductive state in addition to the reset unit 104, and the photoelectric conversion units 101a to 101h are reset in addition to the charge holding unit 103 and the auxiliary charge holding unit 108.

At T2, the input of the on-voltage of the signal lines TG1 to TG8 is stopped. Thus, an exposure period is started.

At T3, the on-voltage is input from the signal line SEL. Thus, the pixel block 200a is selected. In addition, the input of the on-voltage of the reset signal line RST is stopped. Thus, resetting of the charge holding unit 103 and the auxiliary charge holding unit 108 is stopped.

At T4, a signal having a value “0” is input to the signal line AZ-a, and the MOS transistors 320 and 323 constituting the differential pair are reset. Further, the image signal generation unit 110 of the pixel block 200a starts outputting the image signal “A” at the time of reset in the low sensitivity mode.

At T5, the input of the signal having a value “0” to the signal line AZ-a is stopped. In the period from T5 to T6, the reference signal generation unit 34 outputs a ramp function-like reference signal, and the analog-to-digital conversion unit 300 performs analog-to-digital conversion to generate a digital image signal at the reset level in the low sensitivity mode. This period corresponds to a low sensitivity mode reset.

At T6, the input of the on-voltage to the signal line FDG is stopped. Thus, the coupling unit 107 is brought into a non-conductive state and shifts to the high sensitivity mode. In addition, a signal having a value “0” is input to the signal line AZ-b, and the MOS transistors 321 and 322 constituting the differential pair are reset. In addition, a signal having a value “1” is input to the signal line SEL-a, and a signal having a value “0” is input to the signal line SEL-b. Thus, the MOS transistors 321 and 322 constituting the differential pair are selected.

At T7, the input of the signal having a value “0” to the signal line AZ-b is stopped. Further, in the period from T6 to T7, the image signal generation unit 110 of the pixel block 200a starts outputting the image signal “C” at the time of reset in the high sensitivity mode.

In the period from T8 to T9, the reference signal generation unit 34 outputs the reference signal, the analog-to-digital conversion unit 300 performs analog-to-digital conversion, and a digital image signal at the reset level in the high sensitivity mode is generated. This period corresponds to a high sensitivity mode reset.

At T9, the on-voltage is input from the signal line TG1, and the charge transfer unit 102a is brought into a conductive state. Thus, the charge accumulated in the photoelectric conversion unit 101a is transferred to the charge holding unit 103.

At T10, the input of the on-voltage of the signal line TG1 is stopped, and the charge transfer unit 102a is brought into a non-conductive state. In the period from T10 to T11, the image signal generation unit 110 starts outputting the image signal “D”. This image signal corresponds to the first image signal. The period corresponds to the first image signal generation mode.

In the period from T11 to T12, the reference signal generation unit 34 outputs the reference signal, and the analog-to-digital conversion unit 300 performs analog-to-digital conversion to generate a digital first image signal.

At T12, the on-voltage is input from the signal line TG6, and the charge transfer unit 102f is brought into a conductive state. Thus, the charge accumulated in the photoelectric conversion unit 101f is transferred to the charge holding unit 103.

At T13, the input of the on-voltage of the signal line TG6 is stopped, and the charge transfer unit 102f is brought into a non-conductive state. In the period from T14 to T16, the image signal generation unit 110 starts outputting the image signal “E”. This image signal corresponds to the second image signal. The period corresponds to the second image signal generation mode.

At T15, an on-voltage is input to the signal lines TG2 to TG5, TG7, and TG8, and the charge transfer units 102b to 102e, 102g, and 102h are brought into a conductive state. Thus, the charges accumulated in the photoelectric conversion units 101b to 101e, 101g, and 101h are transferred to the charge holding unit 103.

At T16, the input of the on-voltage of the signal line TG2 and the like is stopped, and the charge transfer unit 102b and the like are brought into a non-conductive state. In the period from T17 to T18, the image signal generation unit 110 starts outputting the image signal “F”. This image signal corresponds to the third image signal. This period corresponds to the third image signal generation mode.

At T18, an on-voltage is input to the signal line FDG, and the coupling unit 107 is brought into a conductive state. Thus, the mode shifts to the low sensitivity mode. In addition, a signal having a value “0” is input to the signal line SEL-a, and a signal having a value “1” is input to the signal line SEL-b. Thus, the MOS transistors 320 and 323 constituting the differential pair are selected. In the period from T19 to T21, the image signal generation unit 110 starts outputting the image signal “B”. This image signal corresponds to a fourth image signal. This period corresponds to the fourth image signal generation mode.

At T21, the application of the on-voltage of the signal line SEL is stopped, and the pixel block 200a is brought into a non-selected state. Further, a value “1” is input to the signal line RST. Thus, the state returns to the initial state, and resetting of the charge holding unit 103 and the auxiliary charge holding unit 108 is resumed.

According to the above procedure, the first to fourth image signals can be generated in the pixel block 200a. By switching and using the differential pair of the analog-to-digital conversion unit 300 in the low sensitivity mode and the high sensitivity mode, the analog-to-digital conversion of the image signals in the low sensitivity mode and the high sensitivity mode can be sequentially performed by one analog-to-digital conversion unit 300. Thus, the time required for generating the image signal can be shortened. Furthermore, in the period from T4 to T5, the differential pair including the MOS transistors 320 and 323 is reset by the input of the signal having the value “0” to the signal line AZ-a. At this time, by causing the capacitors 301 and 303 to hold offset components, the two analog-to-digital conversions of the image signal at the reset level and the image signal at the signal level using the differential pair including the MOS transistors 320 and 323 can be performed separately. Therefore, it is possible to generate the image signal at the reset level and the image signal at the signal level in the high sensitivity mode during the generation of the image signal at the reset level and the generation of the image signal at the signal level in the low sensitivity mode. It is possible to sequentially transfer charges corresponding to the low sensitivity mode and the high sensitivity mode in the same frame, and it is possible to prevent a decrease in the frame frequency of the imaging element 1 corresponding to the low sensitivity mode and the high sensitivity mode.

The configuration of the imaging element 1 other than this is similar to the configuration of the imaging element 1 in the first embodiment of the present disclosure, and thus description thereof is omitted.

As described above, the imaging element 1 according to the third embodiment of the present disclosure can generate the phase difference signal by generating image signals of some pixels 100 and performing calculation with the image signals in the low resolution mode and the low sensitivity mode. Thus, the period required for generating the phase difference signal can be shortened.

### 4. Configuration of Imaging Device

A technology according to the present disclosure is applicable to various products. For example, the technology according to the present disclosure can be applied to an imaging device such as a camera.

FIG. 16 is a diagram illustrating a configuration example of an imaging device to which the technology according to the present disclosure can be applied. An imaging device 1000 in the drawing includes an imaging element 1001, a control unit 1002, an image processing unit 1003, a display unit 1004, a recording unit 1005, and an imaging lens 1006.

The imaging lens 1006 is a lens that collects light from a subject. The subject is imaged on a light receiving surface of the imaging element 1001 by the imaging lens 1006.

The imaging element 1001 is an element that images a subject. A plurality of pixels including a photoelectric conversion unit that performs photoelectric conversion of light from a subject is disposed on a light receiving surface of the imaging element 1001. Each of the plurality of pixels generates an image signal based on a charge generated by photoelectric conversion. The imaging element 1001 converts an image signal generated by the pixel into a digital image signal and outputs the digital image signal to the image processing unit 1003. Note that an image signal for one screen is referred to as a frame. The imaging element 1001 can also output an image signal in units of frames.

The control unit 1002 controls the imaging element 1001 and the image processing unit 1003. The control unit 1002 can be configured by, for example, an electronic circuit using a microcomputer or the like.

The image processing unit 1003 processes an image signal from the imaging element 1001. The processing of the image signal in the image processing unit 1003 corresponds to, for example, demosaic processing of generating an image signal of a color that is insufficient when a color image is generated or noise reduction processing of removing noise of the image signal. The image processing unit 1003 can be configured by, for example, an electronic circuit using a microcomputer or the like.

The display unit 1004 displays an image on the basis of the image signal processed by the image processing unit 1003. The display unit 1004 can be configured by, for example, a liquid crystal monitor.

The recording unit 1005 records an image (frame) based on the image signal processed by the image processing unit 1003. The recording unit 1005 can be configured by, for example, a hard disk or a semiconductor memory.

The imaging device to which the present disclosure can be applied has been described above. The present technology can be applied to the imaging element 1001 among the above-described components. Specifically, the imaging element 1 described in FIG. 1 can be applied to the imaging element 1001. Note that the image processing unit 1003 is an example of a processing circuit described in the claims.

### Effects

The imaging element 1 includes a plurality of pixel blocks 200, an auxiliary charge holding unit 108, and a coupling unit 107. The pixel block 200 includes a plurality of pixels 100 each including a photoelectric conversion unit 101 that performs photoelectric conversion of incident light from a subject and a charge transfer unit 102 that transfers a charge generated by the photoelectric conversion, a charge holding unit 103 that holds a charge transferred by the charge transfer unit 102, a reset unit 104 that performs reset by discharging the held charge, and an image signal generation unit 110 that generates an image signal according to the held charge. The auxiliary charge holding unit 108 is coupled to the charge holding unit 103 of each of the plurality of pixel blocks 200. The coupling unit 107 is disposed for each of the plurality of pixel blocks 200 and couples the auxiliary charge holding unit 108 to the charge holding unit 103 by causing conduction between the charge holding unit 103 and the auxiliary charge holding unit 108 of the pixel block 200 of the conducting unit. The image signal generation unit 110 generates the image signal in each of a high sensitivity mode which is an operation mode in which the auxiliary charge holding unit 108 and the charge holding unit 103 are not coupled and a low sensitivity mode which is an operation mode in which the auxiliary charge holding unit 108 and the charge holding unit 103 are coupled. In a case of the low sensitivity mode, the coupling unit 107 causes conduction between the charge holding unit 103 and the auxiliary charge holding unit 108 during an own pixel block charge holding period that is a period in which a charge is held in the charge holding unit 103 of the pixel block 200 of the coupling unit 107 and a charge non-holding period that is a period in which a charge is not held in the charge holding unit 103 of any of the pixel blocks 200. In a case of the low sensitivity mode, the reset unit 104 performs the reset in the charge non-holding period. Thus, the reset period of the auxiliary charge holding unit 108 can be extended.

Furthermore, the coupling unit 107 may perform coupling when an on-voltage configured by a MOS transistor and making itself conductive is applied to the gate.

In addition, in a case of the high sensitivity mode, a middle voltage between an off-voltage that brings the coupling unit 107 into a non-conductive state during the own pixel block 200 charge holding period and the on-voltage may be applied to the gate. Thus, the potential of the coupling unit 107 can be adjusted.

Furthermore, the pixel array unit 10 in which the plurality of pixel block units 220 including the plurality of pixel blocks 200 and the auxiliary charge holding unit 108 coupled to the plurality of pixel blocks 200 via the coupling unit 107 is disposed may be included, in which the pixel blocks 200 may individually transfer the charges of the corresponding photoelectric conversion units 101 to the charge holding unit 103 in a high resolution mode in which the plurality of charge transfer units 102 generates the image signal for each pixel 100, and simultaneously transfer the charges of the corresponding photoelectric conversion units 101 to the charge holding unit 103 in a low resolution mode in which the image signal based on the sum of charges generated by the photoelectric conversion units 101 included in the pixel blocks 200 is generated, and the image signal generation unit 110 may further generate the image signal in each of the high resolution mode and the low resolution mode.

Furthermore, the image processing device may further include an on-chip lens 170 disposed for each of the pixel blocks 200 and disposed in common on the plurality of pixels 100 included in the pixel block 200, and the pixel block 200 may further generate a phase difference signal for the image signal generation unit 110 to perform pupil division on the subject and detect an image plane phase difference.

Furthermore, the pixel blocks 200 may sequentially perform a first image signal generation mode in which the charge transfer unit 102 of one pixel 100 among the plurality of pixels 100 on one side in the pupil division transfers a charge to the charge holding unit 103 and the image signal generation unit 110 generates an image signal in the high sensitivity mode, a second image signal generation mode in which the charge transfer unit 102 of one pixel 100 among the plurality of pixels 100 on the other side in the pupil division further transfers the charge to the charge holding unit 103 and the image signal generation unit 110 generates an image signal in the high sensitivity mode, a third image signal generation mode in which the charge transfer unit 102 of the remaining pixels 100 further transfers the charge to the charge holding unit 103 and the image signal generation unit 110 generates an image signal in the high sensitivity mode, and a fourth image signal generation mode in which the image signal generation unit 110 generates an image signal in the low sensitivity mode, and may output a first image signal that is an image signal in the first image signal generation mode as the phase difference signal on one side of pupil division in the low sensitivity mode, output a second image signal that is an image signal in the second image signal generation mode as an image signal for generating the phase difference signal on the other side of pupil division in the low sensitivity mode, output a third image signal that is an image signal in the third image signal generation mode as an image signal in the high sensitivity mode, and output a fourth image signal that is an image signal in the fourth image signal generation mode as the image signal in the low sensitivity mode. Thus, four image signals can be continuously generated.

Furthermore, an image signal processing unit that generates the phase difference signal on the other side of the pupil division in the low sensitivity mode by subtracting the first image signal from the fourth image signal may be further included. Thus, the phase difference signal can be generated.

Furthermore, the image signal processing unit may further generate the phase difference signal on one side of the pupil division in the high sensitivity mode by adjusting the first image signal according to the ratio of the high sensitivity mode and the low sensitivity mode, and may further generate the phase difference signal on the other side of the pupil division in the high sensitivity mode by adjusting the difference between the fourth image signal and the first image signal according to the ratio of the high sensitivity mode and the low sensitivity mode. Thus, the phase difference signal can be generated.

Furthermore, the on-chip lens 170 may be disposed in common on the plurality of pixels 100 disposed in two rows and two columns, and the pixel block 200 may further generate a second phase difference signal for detecting an image plane phase difference by second pupil division that is pupil division in a direction orthogonal to the pupil division.

Furthermore, the image signal processing unit may generate the phase difference signal on one side of the second pupil division by subtracting the first image signal from the second image signal, and generate the phase difference signal on the other side of the second pupil division by subtracting the first image signal and a signal obtained by multiplying the second image signal by a predetermined constant from the fourth image signal. Thus, the phase difference signal can be generated.

Furthermore, the pixel block 200 may further perform low sensitivity mode reset in which the reset in the low sensitivity mode is performed before the first image signal generation mode, and high sensitivity mode reset in which the reset in the high sensitivity mode is performed after the fourth image signal generation mode, further output the image signal in the low sensitivity mode reset, and further output the image signal in the high sensitivity mode reset. Accordingly, the CDS can be performed.

In addition, an image signal correction unit that corrects the fourth image signal on the basis of the image signal in the low sensitivity mode reset and corrects the first image signal, the second image signal, and the third image signal on the basis of the image signal in the high sensitivity mode reset may be further included. Accordingly, the CDS can be performed.

Furthermore, a control signal generation unit that generates control signals of the charge transfer unit 102, the reset unit 104, the image signal generation unit 110, and the coupling unit 107 in each of the high sensitivity mode and the low sensitivity mode may be further included.

The imaging element 1000 includes a plurality of pixel blocks 200, an auxiliary charge holding unit 108, a coupling unit 107, and an image processing unit 1003. The pixel block 200 includes a plurality of pixels 100 each including a photoelectric conversion unit 101 that performs photoelectric conversion of incident light from a subject and a charge transfer unit 102 that transfers a charge generated by the photoelectric conversion, a charge holding unit 103 that holds a charge transferred by the charge transfer unit 102, a reset unit 104 that performs reset by discharging the held charge, and an image signal generation unit 110 that generates an image signal according to the held charge. The auxiliary charge holding unit 108 is coupled to the charge holding unit 103 of each of the plurality of pixel blocks 200. The coupling unit 107 is disposed for each of the plurality of pixel blocks 200 and couples the auxiliary charge holding unit 108 to the charge holding unit 103 by causing conduction between the charge holding unit 103 and the auxiliary charge holding unit 108 of the pixel block 200 of the conducting unit. The image processing unit 1003 processes the generated image signal. The image signal generation unit 110 generates the image signal in each of a high sensitivity mode which is an operation mode in which the auxiliary charge holding unit 108 and the charge holding unit 103 are not coupled, and a low sensitivity mode which is an operation mode in which the auxiliary charge holding unit 108 and the charge holding unit 103 are coupled. the coupling unit 107 causes, in a case of the low sensitivity mode, conduction between the charge holding unit 103 and the auxiliary charge holding unit 108 during an own pixel block charge holding period that is a period in which a charge is held in the charge holding unit 103 of the pixel block 200 of the coupling unit 107 and a charge non-holding period that is a period in which a charge is not held in the charge holding unit 103 of any of the pixel blocks 200, and the reset unit 104 performs the reset in the charge non-holding period in a case of the low sensitivity mode. Thus, the reset period of the auxiliary charge holding unit 108 can be extended.

Note that the effects described in the present specification are merely examples and are not limited, and other effects may be provided.

Note that the present technology can also have the following configurations.
(1)
   An imaging element, comprising:
   a plurality of pixel blocks each including a plurality of pixels each including a photoelectric conversion unit that performs photoelectric conversion of incident light from a subject and a charge transfer unit that transfers a charge generated by the photoelectric conversion, a charge holding unit that holds a charge transferred by the charge transfer unit, a reset unit that performs reset by discharging the held charge, and an image signal generation unit that generates an image signal according to the held charge;
   an auxiliary charge holding unit coupled to the charge holding unit of each of the plurality of pixel blocks; and
   a coupling unit that is disposed for each of the plurality of pixel blocks and couples the auxiliary charge holding unit to the charge holding unit by causing conduction between the charge holding unit and the auxiliary charge holding unit of the pixel block containing the coupling unit, wherein
   the image signal generation unit generates the image signal in each of a high sensitivity mode which is an operation mode in which the auxiliary charge holding unit and the charge holding unit are not coupled and a low sensitivity mode which is an operation mode in which the auxiliary charge holding unit and the charge holding unit are coupled,
   the coupling unit causes, in a case of the low sensitivity mode, conduction between the charge holding unit and the auxiliary charge holding unit during an own pixel block charge holding period that is a period in which a charge is held in the charge holding unit of the pixel block of the coupling unit and a charge non-holding period that is a period in which a charge is not held in the charge holding unit of any of the pixel blocks, and
   the reset unit performs the reset in the charge non-holding period in a case of the low sensitivity mode.
(2)
   The imaging element according to the above (1), wherein the coupling unit performs the coupling when an on-voltage configured by a MOS transistor and making the coupling unit conductive is applied to a gate.
(3)
   The imaging element according to the above (2), in which in a case of the high sensitivity mode, a middle voltage between an off-voltage that brings the coupling unit into a non-conductive state during the own pixel block charge holding period and the on-voltage is applied to the gate.
(4)
   The imaging element according to the above (1) or (2), further comprising:
   a pixel array unit in which a plurality of pixel block units including the plurality of pixel blocks and the auxiliary charge holding unit coupled to the plurality of pixel blocks via the coupling unit is disposed, wherein
   the pixel blocks individually transfer charges of the corresponding photoelectric conversion units to the charge holding unit in a high resolution mode in which a plurality of charge transfer units generates the image signal for each pixel, and simultaneously transfer the charges of the corresponding photoelectric conversion units to the charge holding unit in a low resolution mode in which the image signal based on a sum of charges generated by the photoelectric conversion units included in the pixel blocks is generated, and the image signal generation unit further generates the image signal in each of the high resolution mode and the low resolution mode.
(5)
   The imaging element according to the above (4), further comprising:
   an on-chip lens disposed for each of the pixel blocks and disposed in common on a plurality of the pixels included in the pixel block, wherein
   the pixel block further generates a phase difference signal for the image signal generation unit to perform pupil division on the subject and detect an image plane phase difference.
(6)
   The imaging element according to the above (5), wherein
   the pixel blocks
   sequentially perform a first image signal generation mode in which the charge transfer unit of one of a plurality of the pixels on one side in the pupil division transfers the charge to the charge holding unit and the image signal generation unit generates an image signal in the high sensitivity mode, a second image signal generation mode in which the charge transfer unit of one of a plurality of the pixels on the other side in the pupil division further transfers the charge to the charge holding unit and the image signal generation unit generates an image signal in the high sensitivity mode, a third image signal generation mode in which the charge transfer unit of the remaining pixels further transfers the charge to the charge holding unit and the image signal generation unit generates an image signal in the high sensitivity mode, and a fourth image signal generation mode in which the image signal generation unit generates an image signal in the low sensitivity mode, and
   output a first image signal that is an image signal in the first image signal generation mode as the phase difference signal on one side of the pupil division in the low sensitivity mode, output a second image signal that is an image signal in the second image signal generation mode as an image signal for generating the phase difference signal on the other side of the pupil division in the low sensitivity mode, output a third image signal that is an image signal in the third image signal generation mode as the image signal in the high sensitivity mode, and output a fourth image signal that is an image signal in the fourth image signal generation mode as the image signal in the low sensitivity mode.
(7)
   The imaging element according to the above (6), further comprising: an image signal processing unit that generates the phase difference signal on the other side of the pupil division in the low sensitivity mode by subtracting the first image signal from the fourth image signal.
(8)
   The imaging element according to the above (7), wherein the image signal processing unit further generates the phase difference signal on one side of the pupil division in the high sensitivity mode by adjusting the first image signal according to a ratio of the high sensitivity mode and the low sensitivity mode, and further generates the phase difference signal on the other side of the pupil division in the high sensitivity mode by adjusting a difference between the fourth image signal and the first image signal according to a ratio of the high sensitivity mode and the low sensitivity mode.
(9)
   The imaging element according to the above (8), wherein
   the on-chip lens is disposed in common on a plurality of the pixels disposed in two rows and two columns, and
   the pixel block further generates a second phase difference signal for detecting an image plane phase difference by second pupil division that is pupil division in a direction orthogonal to the pupil division.
(10)
   The imaging element according to claim 9, wherein the image signal processing unit generates the phase difference signal on one side of the second pupil division by subtracting the first image signal from the second image signal, and generates the phase difference signal on the other side of the second pupil division by subtracting the first image signal and a signal obtained by multiplying the second image signal by a predetermined constant from the fourth image signal.
(11)
   The imaging element according to any one of the above (6) to (10), in which
   the pixel block further performs low sensitivity mode reset in which the reset in the low sensitivity mode is performed before the first image signal generation mode, and high sensitivity mode reset in which the reset in the high sensitivity mode is performed after the fourth image signal generation mode, and
   further outputs the image signal in the low sensitivity mode reset, and further outputs the image signal in the high sensitivity mode reset.
(12)
   The imaging element according to the above (11), further comprising: an image signal correction unit that corrects the fourth image signal on a basis of the image signal in the low sensitivity mode reset and corrects the first image signal, the second image signal, and the third image signal on a basis of the image signal in the high sensitivity mode reset.
(13)
   The imaging element according to any one of the above (6) to (12), further comprising: a control signal generation unit that generates control signals of the charge transfer unit, the reset unit, the image signal generation unit, and the coupling unit in each of the high sensitivity mode and the low sensitivity mode.
(14)
   An imaging device, comprising:
   a plurality of pixel blocks each including a plurality of pixels each including a photoelectric conversion unit that performs photoelectric conversion of incident light from a subject and a charge transfer unit that transfers a charge generated by the photoelectric conversion, a charge holding unit that holds a charge transferred by the charge transfer unit, a reset unit that performs reset by discharging the held charge, and an image signal generation unit that generates an image signal according to the held charge;
   an auxiliary charge holding unit coupled to the charge holding unit of each of the plurality of pixel blocks;
   a coupling unit that is disposed for each of the plurality of pixel blocks and couples the auxiliary charge holding unit to the charge holding unit by causing conduction between the charge holding unit and the auxiliary charge holding unit of the pixel block containing the coupling unit; and
   a processing circuit that processes the generated image signal, wherein
   the image signal generation unit generates the image signal in each of a high sensitivity mode which is an operation mode in which the auxiliary charge holding unit and the charge holding unit are not coupled and a low sensitivity mode which is an operation mode in which the auxiliary charge holding unit and the charge holding unit are coupled,
   the coupling unit causes, in a case of the low sensitivity mode, conduction between the charge holding unit and the auxiliary charge holding unit during an own pixel block charge holding period that is a period in which a charge is held in the charge holding unit of the pixel block of the coupling unit and a charge non-holding period that is a period in which a charge is not held in the charge holding unit of any of the pixel blocks, and
   the reset unit performs the reset in the charge non-holding period in a case of the low sensitivity mode.

### REFERENCE SIGNS LIST

1 IMAGING ELEMENT
10 PIXEL ARRAY UNIT
30 COLUMN SIGNAL PROCESSING UNIT
100, 100a, 100b, 100c, 100d PIXEL
101, 101a, 101b, 101c, 101d, 101e, 101f, 101g, 101h PHOTOELECTRIC CONVERSION UNIT
102a, 102b, 102c, 102d, 102e, 102f, 102g, 102h CHARGE TRANSFER UNIT
103, 103a CHARGE HOLDING UNIT
104 RESET UNIT
107 COUPLING UNIT
108 AUXILIARY CHARGE HOLDING UNIT
110 IMAGE SIGNAL GENERATION UNIT
150 COLOR FILTER
170 ON-CHIP LENS
200, 200a, 200b PIXEL BLOCK
220 PIXEL BLOCK UNIT
1000 IMAGING DEVICE
1003 IMAGE PROCESSING UNIT

1. An imaging element, comprising:
a plurality of pixel blocks each including a plurality of pixels each including a photoelectric conversion unit that performs photoelectric conversion of incident light from a subject and a charge transfer unit that transfers a charge generated by the photoelectric conversion, a charge holding unit that holds a charge transferred by the charge transfer unit, a reset unit that performs reset by discharging the held charge, and an image signal generation unit that generates an image signal according to the held charge;
an auxiliary charge holding unit coupled to the charge holding unit of each of the plurality of pixel blocks; and
a coupling unit that is disposed for each of the plurality of pixel blocks and couples the auxiliary charge holding unit to the charge holding unit by causing conduction between the charge holding unit and the auxiliary charge holding unit of the pixel block containing the coupling unit, wherein
the image signal generation unit generates the image signal in each of a high sensitivity mode which is an operation mode in which the auxiliary charge holding unit and the charge holding unit are not coupled and a low sensitivity mode which is an operation mode in which the auxiliary charge holding unit and the charge holding unit are coupled,
the coupling unit causes, in a case of the low sensitivity mode, conduction between the charge holding unit and the auxiliary charge holding unit during an own pixel block charge holding period that is a period in which a charge is held in the charge holding unit of the pixel block of the coupling unit and a charge non-holding period that is a period in which a charge is not held in the charge holding unit of any of the pixel blocks, and
the reset unit performs the reset in the charge non-holding period in a case of the low sensitivity mode.

2. The imaging element according to claim 1, wherein the coupling unit performs the coupling when an on-voltage configured by a MOS transistor and making the coupling unit conductive is applied to a gate.

3. The imaging element according to claim 2, wherein in a case of the high sensitivity mode, a middle voltage between an off-voltage that brings the coupling unit into a non-conductive state during the own pixel block charge holding period and the on-voltage is applied to the gate.

4. The imaging element according to claim 1, further comprising:
a pixel array unit in which a plurality of pixel block units including the plurality of pixel blocks and the auxiliary charge holding unit coupled to the plurality of pixel blocks via the coupling unit is disposed, wherein
the pixel blocks individually transfer charges of the corresponding photoelectric conversion units to the charge holding unit in a high resolution mode in which a plurality of charge transfer units generates the image signal for each pixel, and simultaneously transfer the charges of the corresponding photoelectric conversion units to the charge holding unit in a low resolution mode in which the image signal based on a sum of charges generated by the photoelectric conversion units included in the pixel blocks is generated, and the image signal generation unit further generates the image signal in each of the high resolution mode and the low resolution mode.

5. The imaging element according to claim 4, further comprising:
an on-chip lens disposed for each of the pixel blocks and disposed in common on a plurality of the pixels included in the pixel block, wherein
the pixel block further generates a phase difference signal for the image signal generation unit to perform pupil division on the subject and detect an image plane phase difference.

6. The imaging element according to claim 5, wherein
the pixel blocks
sequentially perform a first image signal generation mode in which the charge transfer unit of one of a plurality of the pixels on one side in the pupil division transfers the charge to the charge holding unit and the image signal generation unit generates an image signal in the high sensitivity mode, a second image signal generation mode in which the charge transfer unit of one of a plurality of the pixels on the other side in the pupil division further transfers the charge to the charge holding unit and the image signal generation unit generates an image signal in the high sensitivity mode, a third image signal generation mode in which the charge transfer unit of the remaining pixels further transfers the charge to the charge holding unit and the image signal generation unit generates an image signal in the high sensitivity mode, and a fourth image signal generation mode in which the image signal generation unit generates an image signal in the low sensitivity mode, and
output a first image signal that is an image signal in the first image signal generation mode as the phase difference signal on one side of the pupil division in the low sensitivity mode, output a second image signal that is an image signal in the second image signal generation mode as an image signal for generating the phase difference signal on the other side of the pupil division in the low sensitivity mode, output a third image signal that is an image signal in the third image signal generation mode as the image signal in the high sensitivity mode, and output a fourth image signal that is an image signal in the fourth image signal generation mode as the image signal in the low sensitivity mode.

7. The imaging element according to claim 6, further comprising: an image signal processing unit that generates the phase difference signal on the other side of the pupil division in the low sensitivity mode by subtracting the first image signal from the fourth image signal.

8. The imaging element according to claim 7, wherein the image signal processing unit further generates the phase difference signal on one side of the pupil division in the high sensitivity mode by adjusting the first image signal according to a ratio of the high sensitivity mode and the low sensitivity mode, and further generates the phase difference signal on the other side of the pupil division in the high sensitivity mode by adjusting a difference between the fourth image signal and the first image signal according to a ratio of the high sensitivity mode and the low sensitivity mode.

9. The imaging element according to claim 8, wherein
the on-chip lens is disposed in common on a plurality of the pixels disposed in two rows and two columns, and
the pixel block further generates a second phase difference signal for detecting an image plane phase difference by second pupil division that is pupil division in a direction orthogonal to the pupil division.

10. The imaging element according to claim 9, wherein the image signal processing unit generates the phase difference signal on one side of the second pupil division by subtracting the first image signal from the second image signal, and generates the phase difference signal on the other side of the second pupil division by subtracting the first image signal and a signal obtained by multiplying the second image signal by a predetermined constant from the fourth image signal.

11. The imaging element according to claim 6, wherein
the pixel block further performs low sensitivity mode reset in which the reset in the low sensitivity mode is performed and high sensitivity mode reset in which the reset in the high sensitivity mode is performed before the first image signal generation mode, and
further outputs an image signal in the low sensitivity mode reset, and further outputs an image signal in the high sensitivity mode reset.

12. The imaging element according to claim 11, further comprising: an image signal correction unit that corrects the fourth image signal on a basis of the image signal in the low sensitivity mode reset and corrects the first image signal, the second image signal, and the third image signal on a basis of the image signal in the high sensitivity mode reset.

13. The imaging element according to claim 1, further comprising: a control signal generation unit that generates control signals of the charge transfer unit, the reset unit, the image signal generation unit, and the coupling unit in each of the high sensitivity mode and the low sensitivity mode.

14. An imaging device, comprising:
a plurality of pixel blocks each including a plurality of pixels each including a photoelectric conversion unit that performs photoelectric conversion of incident light from a subject and a charge transfer unit that transfers a charge generated by the photoelectric conversion, a charge holding unit that holds a charge transferred by the charge transfer unit, a reset unit that performs reset by discharging the held charge, and an image signal generation unit that generates an image signal according to the held charge;
an auxiliary charge holding unit coupled to the charge holding unit of each of the plurality of pixel blocks;
a coupling unit that is disposed for each of the plurality of pixel blocks and couples the auxiliary charge holding unit to the charge holding unit by causing conduction between the charge holding unit and the auxiliary charge holding unit of the pixel block containing the coupling unit; and
a processing circuit that processes the generated image signal, wherein
the image signal generation unit generates the image signal in each of a high sensitivity mode which is an operation mode in which the auxiliary charge holding unit and the charge holding unit are not coupled and a low sensitivity mode which is an operation mode in which the auxiliary charge holding unit and the charge holding unit are coupled,
the coupling unit causes, in a case of the low sensitivity mode, conduction between the charge holding unit and the auxiliary charge holding unit during an own pixel block charge holding period that is a period in which a charge is held in the charge holding unit of the pixel block of the coupling unit and a charge non-holding period that is a period in which a charge is not held in the charge holding unit of any of the pixel blocks, and
the reset unit performs the reset in the charge non-holding period in a case of the low sensitivity mode.
